(19) United States
(12) Patent Application Publication
(10) Pub. No.: US 2006/0001035 A1
(43) Pub. Date: Jan. 5, 2006

(54) Light emitting element and method of making same

(75) Inventors: Yoshinobu Suehiro, Aichi-ken (JP); Satoshi Wada, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Toyoda Gosei Co., Ltd., Aichi-ken (JP)

(21) Appl. No.: 11/157,174

(22) Filed: Jun. 21, 2005

(30) Foreign Application Priority Data
Jun. 22, 2004 (JP) 2004-184028
Aug. 31, 2004 (JP) 2004-252499

(51) Int. Cl. H01L 29/205; H01L 21/00

(52) U.S. Cl. 257/91; 257/103; 257/99; 438/22

(57) ABSTRACT

A light emitting element has: a semiconductor layer having a light-emitting layer; a first electrode; a second electrode; an insulation layer that is formed on a mounting face side of the semiconductor layer; and a first terminal and a second terminal that are formed on a surface of the insulation layer corresponding to the first electrode and the second electrode, respectively. The first electrode and the second electrode are formed on the mounting face side of the semiconductor layer. The insulation layer has a first opening and a second opening, and the first electrode and the second electrode are electrically connected through the first hole and the second hole, respectively, to the first terminal and the second terminal.

The present application is based on Japanese patent application Nos. 2004-184028 and 2004-252499, the entire contents of which are incorporated herein by reference.

### BACKGROUND OF THE INVENTION

1. Field of the Invention

This invention relates to a light emitting element and, particularly, to a light emitting element that has an increased emission area relative to the element's surface area and prevents unevenness in light distribution so as to increase brightness thereof. Also, this invention relates to a light emitting element that has an excellent mounting performance, a high reliability in electrical connection, and a heat radiation performance as well as having an increased emission area relative to the element's surface area. Further, this invention relates to a method of making the light emitting element thus featured while using the conventional apparatus without requiring any advance technique.

Herein, a light emitting element includes a light emitting device, a light emitting diode (LED) and an LED element.

2. Description of the Related Art

A light emitting element (herein also referred to as LED element) is known in which a group III nitride-based compound semiconductor is grown on a transparent underlying substrate such as sapphire. Also, it is known that the LED element is flip-chip mounted on a mounting board to extract light from the underlying substrate side since the underlying substrate is transparent (for example, see JP-A-2002-232016, paragraph 0005).

JP-A-2002-233016 discloses a flip-chip mounting method that an LED element is carried onto a submount board with bumps attached corresponding to a p-electrode and an n-electrode of the LED element while being in vacuum contact with a vacuum head. In process of the method, the posture of the LED element is controlled such that the n-electrode of the LED element is mounted on the p-electrode bump of the submount board and p-electrode of the LED element is mounted on the n-electrode bump of the submount board. Then, by applying ultrasonic vibration to the LED element, the LED element is pressure-bonded to the submount board while allowing the bumps to be pushed down.

FIG. 12 is a perspective view showing an electrode forming surface of the LED element. The LED element 30 comprises: a transparent sapphire substrate 31; a buffer layer 32 formed on the sapphire substrate 31; an n-type semiconductor layer 33 formed on the buffer layer 32; a light-emitting layer 34 formed on the n-type semiconductor layer 33 to emit light based on the radiative recombination of hole and electron; a p-type semiconductor layer 35 formed on the light-emitting layer 34; the n-electrode 36 which is formed on part of the n-type semiconductor layer 33 exposed by partially etching the p-type semiconductor layer 35 to the n-type semiconductor layer 33; and the p-electrode 36 which is formed on the p-type semiconductor layer 35 and whose surface area is defined except the exposed part of the n-type semiconductor layer 33.

However, in the above LED element, the p-electrode and the n-electrode each needs to have a certain electrode area to facilitate the wire bonding in the flip-chip mounting. Especially, since the p-electrode area corresponding to the emission area is reduced due to the n-electrode area, the rate of the emission area relative to the element's surface area must be reduced. Therefore, a large current cannot be applied thereto since the current density of the light-emitting layer becomes too high.

Further, since about ¼ of the element's surface area becomes nonradiative portion due to the n-electrode area, a non-uniform light pattern is generated. When the LED element is used in combination with a convergence optical system, the non-uniform light pattern is radiated and focused. Therefore, it is difficult to enhance the brightness or to improve the light distribution.

To solve the above problems, an LED element is suggested in which electrodes for applying a voltage to an n-type semiconductor layer and a p-type semiconductor layer of the LED element are provided on the side face of the LED element (for example, see JP-A-B-102552, paragraphs 0024 to 0032 and FIG. 1 thereof).

JP-A-8-102552 (FIG. 1) discloses the LED element that insulation layers of SiO₂ are formed on the side faces of a semiconductor layer and a sapphire substrate. One of the insulation layers is etched at part corresponding to an end face of a p-type GaN layer at the top of semiconductor layers of the LED element, and the other of the insulation layers is etched at part corresponding to an end face of an n-type GaN layer. A p-electrode and an n-electrode each are formed on the insulation layer as a conductive film electrically connected to the p-type GaN layer and the n-type GaN layer through the etched part.

In the above LED element, since no electrode is formed on the surface (light extraction surface) of the semiconductor layer, light emitted from the light-emitting layer can be efficiently radiated upward without being blocked by any electrode. Further, since the area of the light-emitting layer is not reduced by etching, the light-emitting layer can have the same area as the sapphire substrate. Therefore, the mount of light radiated from the top face of the semiconductor layer increases and thereby the emission intensity can be enhanced.

However, the LED element of JP-A-8-103055 needs a process that, after a wafer is fabricated by forming the semiconductor layers on the sapphire substrate and then the wafer is diced into chips, the insulation layer is partially etched and the p- and n-electrodes are formed at the etched part through which they are electrically connected to the p-type GaN layer and the n-type GaN layer. Thus, since each chip needs to be processed by using a microscopic and advanced technique, it is difficult to produce the LED element in mass production. Further, in the LED element, although the electrical connection performance is enhanced, the heat radiation performance is insufficient for heat generated during the operation. Therefore, the emission efficiency must be reduced that much.

### SUMMARY OF THE INVENTION

It is an object of the invention to provide a light emitting element that has an increased emission area relative to the element's surface area and prevents unevenness in light distribution so as to increase brightness thereof.

It is a further object of the invention to provide a light emitting element that has an excellent mounting performance, a high reliability in electrical connection, and a heat radiation performance as well as having an increased emission area relative to the element's surface area.

It is a further object of the invention to provide a method of making the light emitting element thus featured while using the conventional apparatus without requiring any advance technique.

(1) According to one aspect of the invention, a light emitting element comprises:

a semiconductor layer comprising a light-emitting layer;

a first electrode that is defined corresponding to the light-emitting layer to supply power to the light-emitting layer;

a second electrode that is defined as a counter electrode of the first electrode;

an insulation layer than is formed on a mounting face side of the semiconductor layer; and

a first terminal and a second terminal that are formed on a surface of the insulation layer corresponding to the first electrode and the second electrode, respectively,

wherein the first electrode and the second electrode are formed on the mounting face side of the semiconductor layer,

the insulation layer comprises a first opening and a second opening that are formed corresponding to the first electrode and the second electrode, respectively, and

the first electrode and the second electrode are electrically connected through the first hole and the second hole, respectively, to the first terminal and the second terminal.

(2) According to another aspect of the invention, a light emitting element comprises:

a semiconductor layer comprising a light-emitting layer;

a first electrode that is defined corresponding to the light-emitting layer to supply power to the light-emitting layer;

a second electrode that is defined as a counter electrode of the first electrode;

wherein the first electrode and the second electrode are formed on the mounting face side of the semiconductor layer, and

the light-emitting layer and the first electrode are surrounded by the second electrode

(3) According to another aspect of the invention, a light emitting element comprises:

a semiconductor layer comprising a light-emitting layer; and

an n-type electrode and a p-type electrode to supply power to the light-emitting layer,

wherein the n-type electrode and the p-type electrode are provided at a periphery of the semiconductor layer that has a width smaller than an entire width of the light emitting element.

(4) According to another aspect of the invention, a method of making a light emitting element comprises:

a semiconductor layer formation step of forming a semiconductor layer comprising a light-emitting layer by stacking a semiconductor material on a wafer underlying substrate;

a semiconductor layer removal step of partially removing the semiconductor layer in a predetermined width and a predetermined depth from a surface of the semiconductor layer to formed an exposed portion;

an electrode formation step of forming electrodes to supply power to an n-type layer and a p-type layer of the semiconductor layer at the exposed portion; and

an element formation step of cutting the underlying substrate with the semiconductor layer into a light emitting element to allow the electrodes to be exposed to a periphery of the light emitting element

(Advantages of the Invention)

In the invention, since the p-type and n-type electrodes can be varied in arbitrary form, the light emitting element can have an increased emission area relative to the element's surface area and prevent unevenness in light distribution so as to increase brightness thereof.

Further, the light emitting element can have an excellent mounting performance, a high reliability in electrical connection, and a heat radiation performance even in a large size type.

In addition, the method of making the light emitting element can be conducted by using the conventional apparatus without requiring any advance technique.

### BRIEF DESCRIPTION OF THE DRAWINGS

The preferred embodiments according to the invention will be explained below referring to the drawings, wherein:

FIG. 1A is a cross sectional view showing an LED element in a first preferred embodiment according to the invention, where the LED element is cut in a diagonal line thereof;

FIG. 1B is a top view showing the form of a p-electrode and an n-electrode in the LED element in FIG. 1A;

FIG. 1C is a top view showing an insulation layer with an opening in the LED element in FIG. 1A;

FIG. 1D is a top view showing a p-terminal portion and an n-terminal portion in the LED element in FIG. 1A;

FIG. 2A is a cross sectional view showing an LED element in a second preferred embodiment according to the invention, where the LED element is cut in a diagonal line thereof;

FIG. 2B is a top view showing the form of a p-electrode and an n-electrode in the LED element in FIG. 2A;

FIG. 2C is a top view showing an insulation layer with an opening in the LED element in FIG. 2A;

FIG. 2D is a top view showing a p-terminal portion and an n-terminal portion in the LED element in FIG. 2A;

FIG. 2E is a top view showing a modification of the n-electrode in FIG. 2B;

FIGS. 3A to 3E are top views showing modifications of the n-electrode and the p-electrode in the LED element of the second embodiment;

FIG. 4A is a top view showing a modification of the insulation layer in the LED element of the second embodiment;

FIG. 4B is a cross sectional view showing the insulation layer in FIG. 4A;

FIG. 5A is a cross sectional view showing an LED element in a third preferred embodiment according to the invention, where the LED element is cut in a diagonal line thereof;

FIG. 5B is a top view showing the form of a p-electrode and an n-electrode in the LED element in FIG. 5A;

FIG. 5C is a top view showing an insulation layer with an opening in the LED element in FIG. 5A;

FIG. 5D is a top view showing a p-terminal portion and an n-terminal portion in the LED element in FIG. 5A;

FIG. 6 is a cross sectional view showing an LED element in a fourth preferred embodiment according to the invention;

FIG. 7A is a top view showing the form of a p-electrode is and an n-electrode in a fifth preferred embodiment according to the invention;

FIG. 7B is a top view showing a p-terminal portion and an n-terminal portion in the LED element in FIG. 7A;

FIG. 9A is a top view showing the form of a p-electrode and an n-electrode in a sixth preferred embodiment according to the invention;

FIG. 8B is a top view showing a p-terminal portion and an n-terminal portion in the LED element in FIG. 8A;

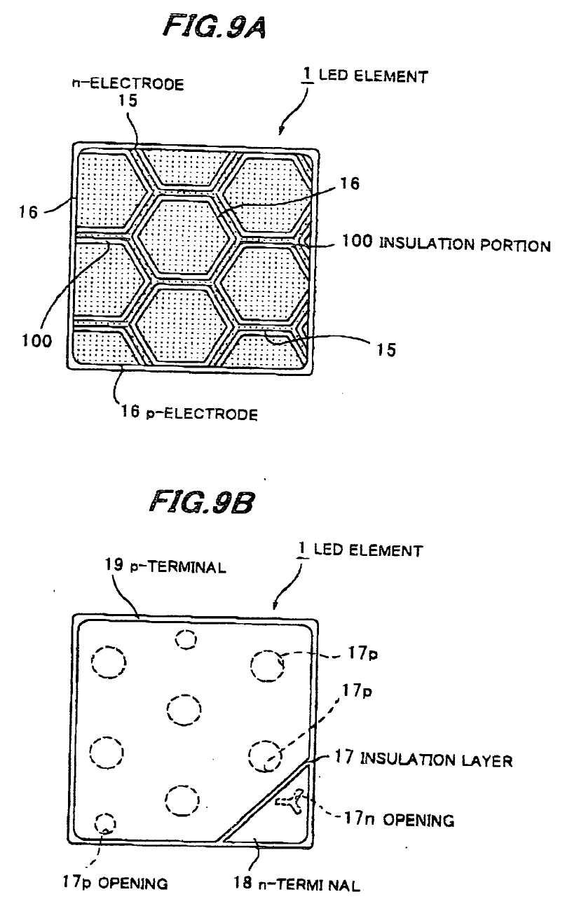

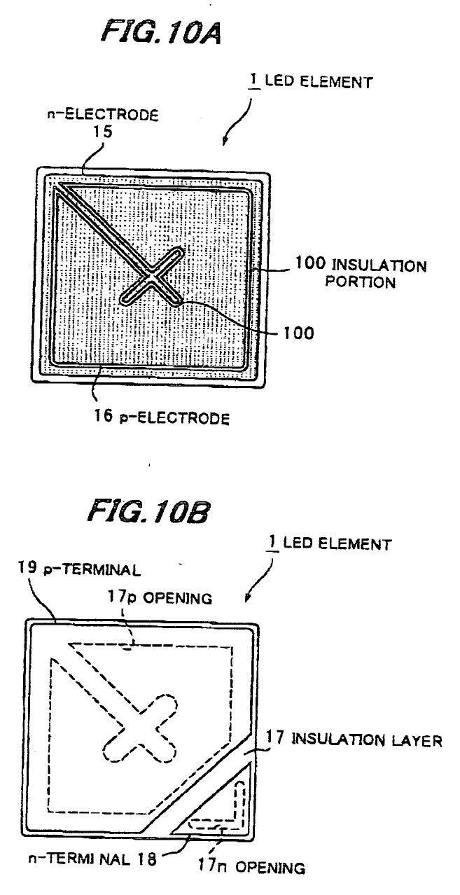

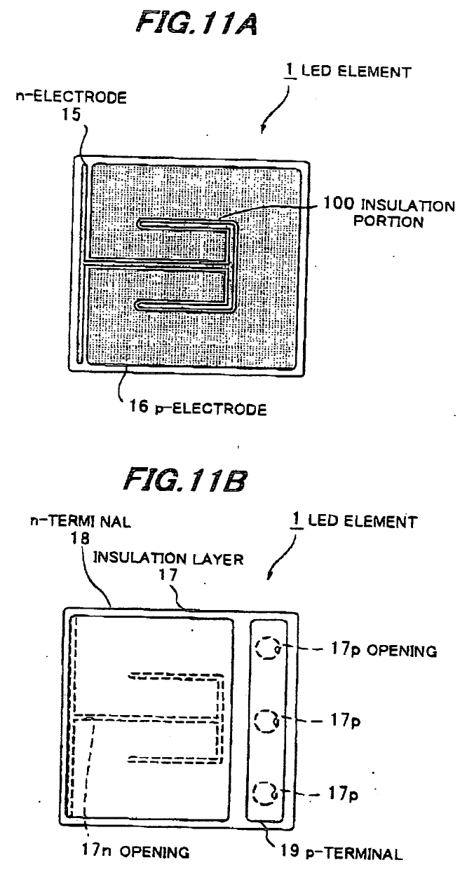

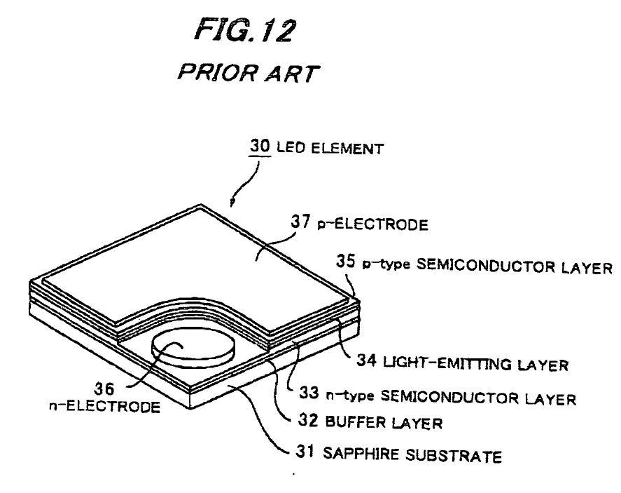

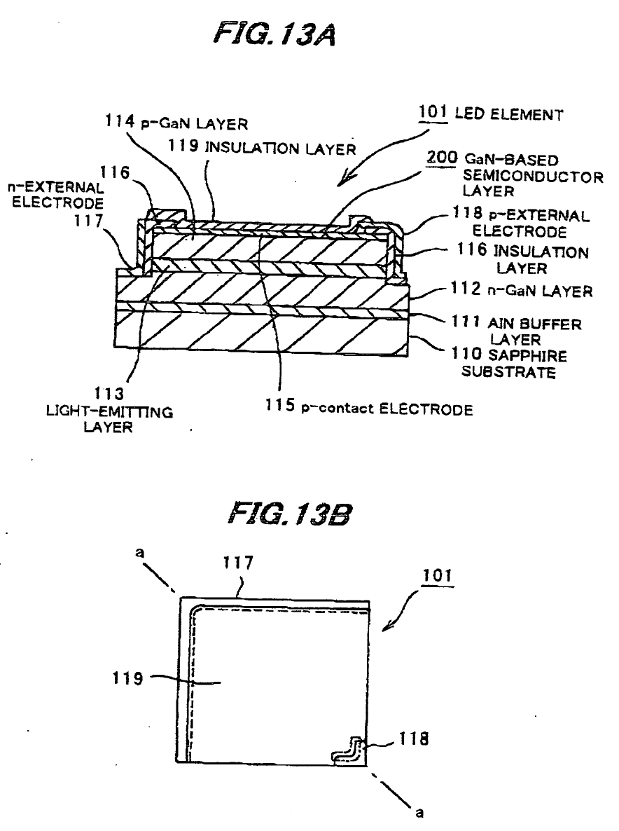

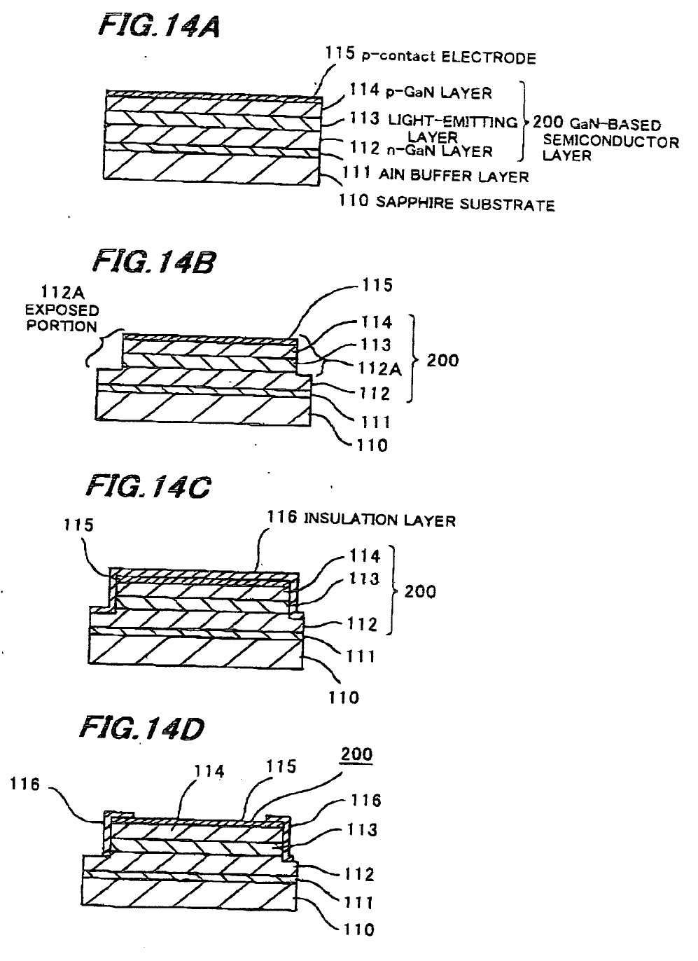

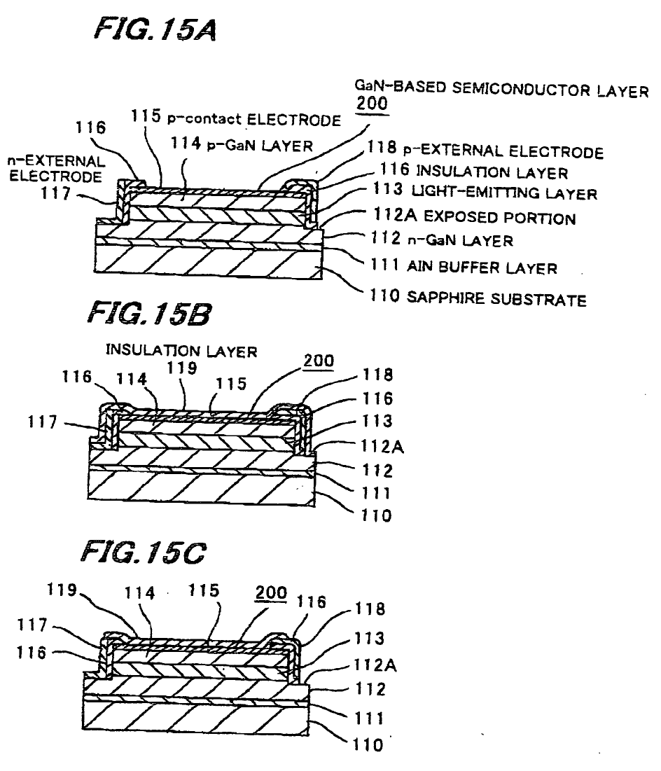

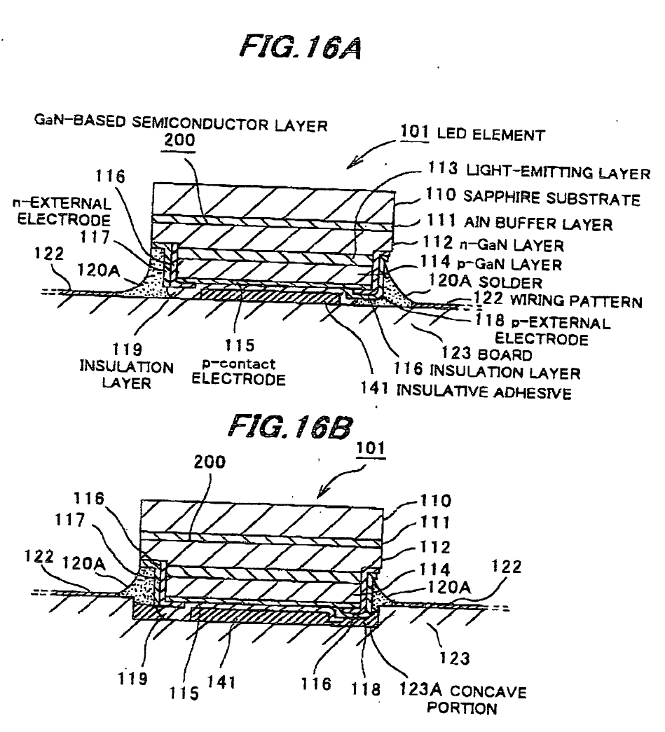

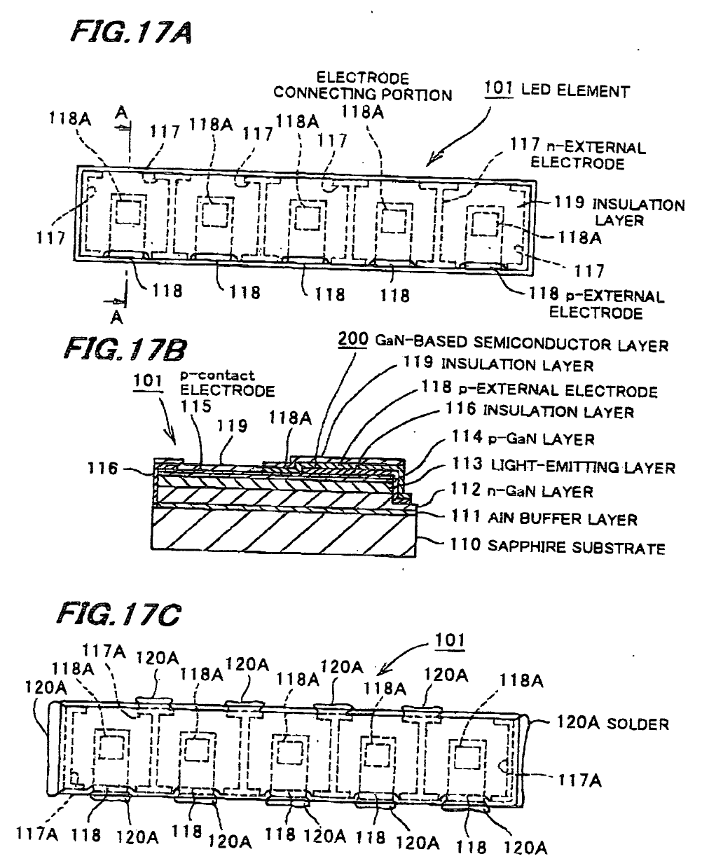

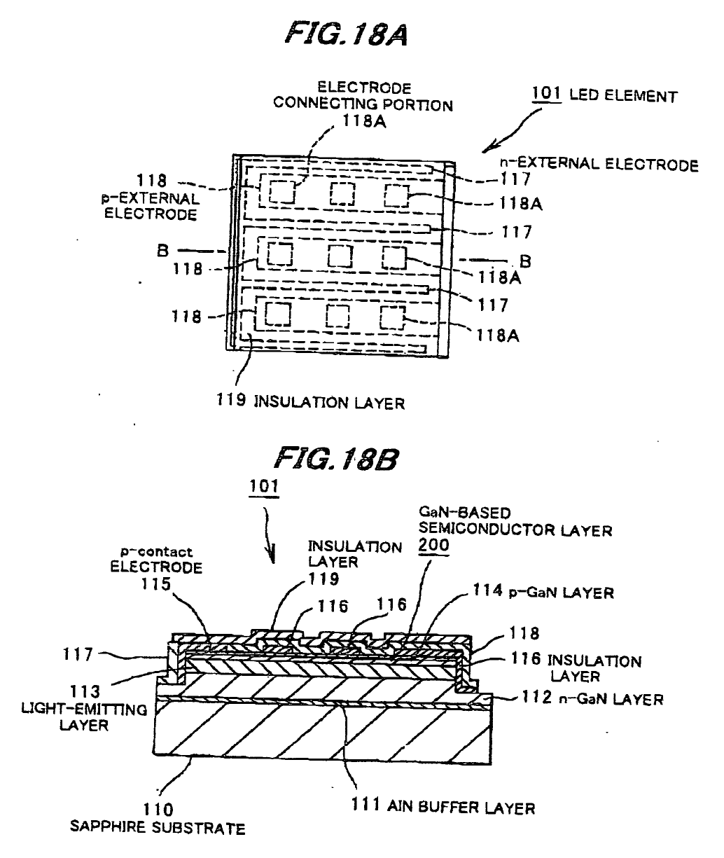

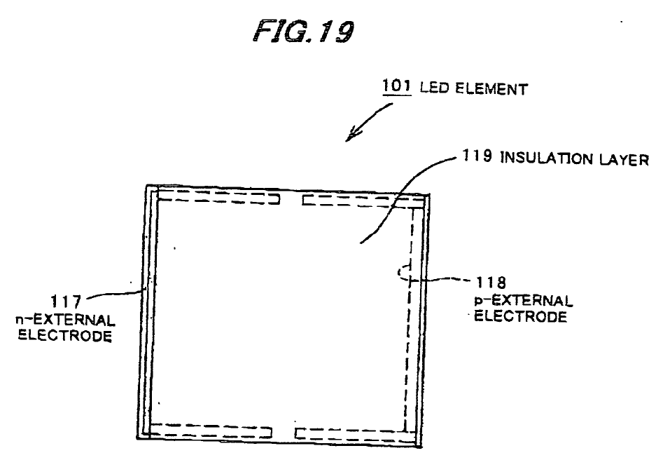

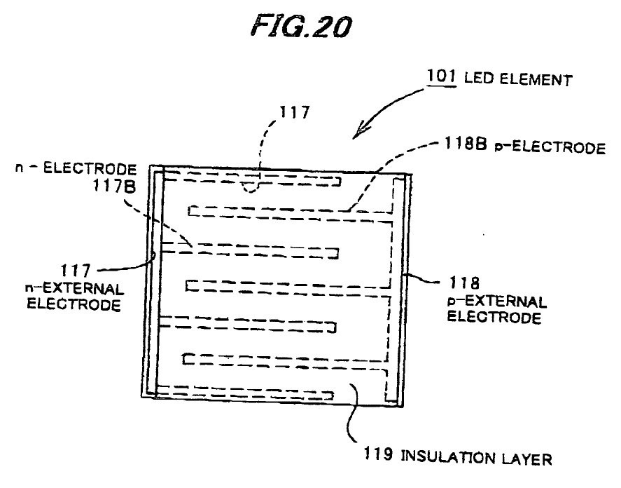

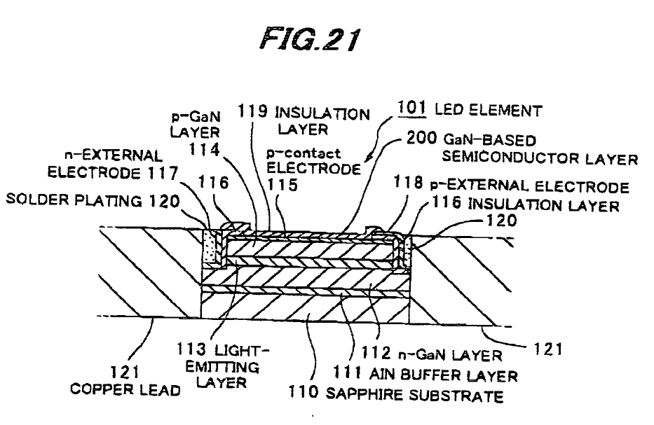

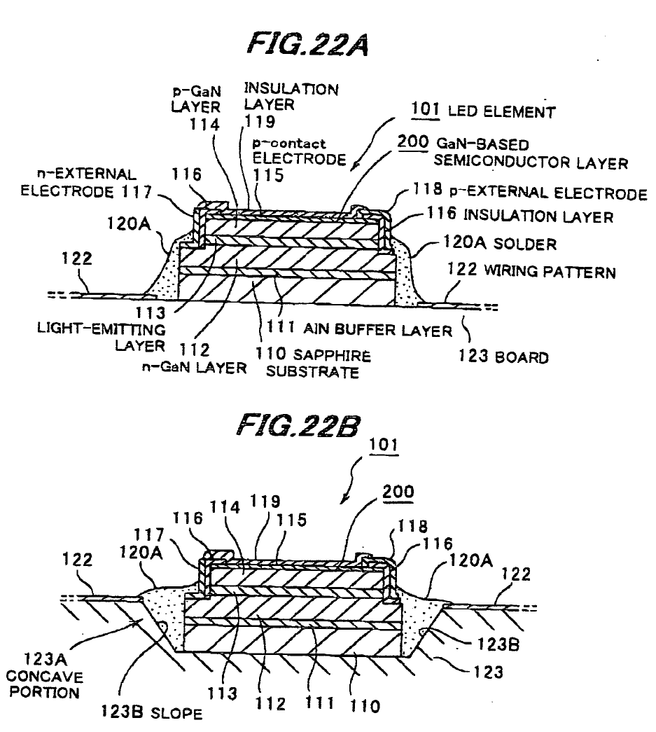

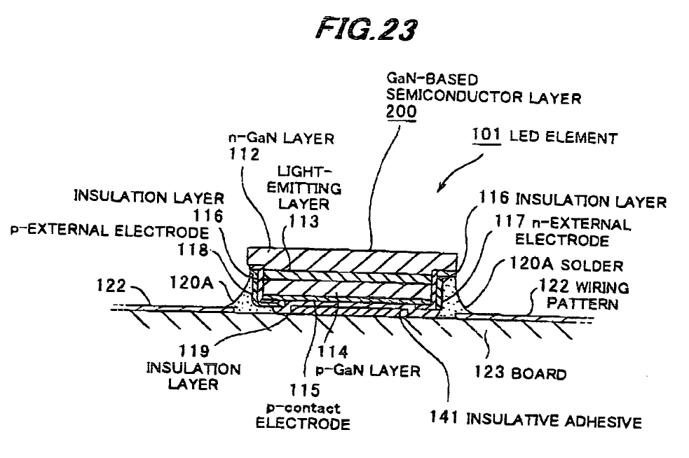

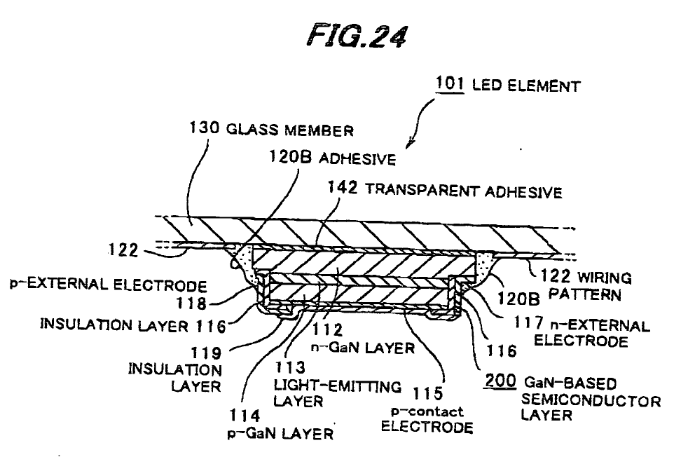

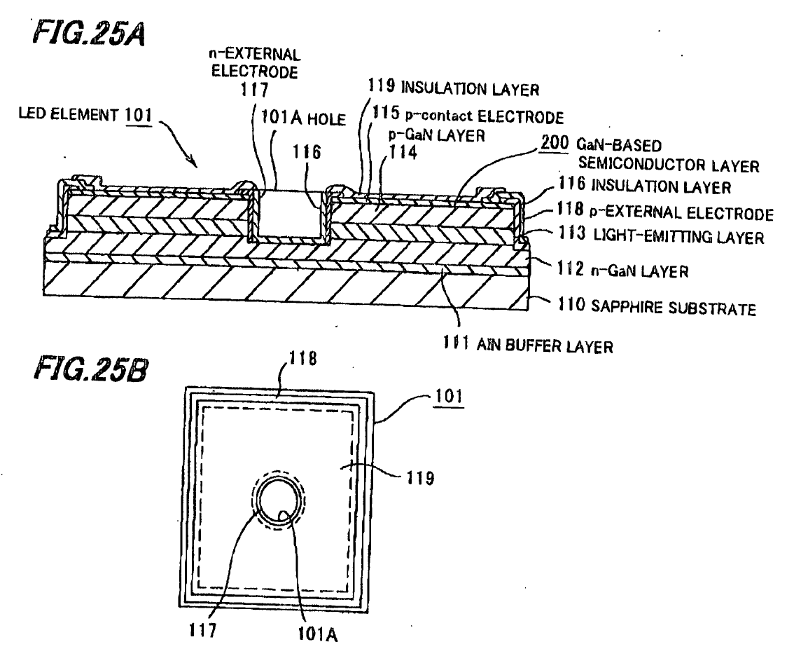

FIG. 9A is a top view showing the form of a p-electrode and an n-electrode in a seventh preferred embodiment according to the invention;

FIG. 9B is a top view showing a p-terminal portion and an n-terminal portion in the LED element in FIG. 9A;

FIG. 10A is a top view showing the form of a p-electrode and an n-electrode in an eighth preferred embodiment according to the invention;

FIG. 10B is a top view showing a p-terminal portion and an n-terminal portion in the LED element in FIG. 10A;

FIG. 11A is a top view showing the form of a p-electrode and an n-electrode in a ninth preferred embodiment according to the invention;

FIG. 11B is a top view showing a p-terminal portion and an n-terminal portion in the LED element in FIG. 11A;

FIG. 12 is a perspective view showing the conventional LED element;

FIG. 13A is a cross sectional view showing an LED element in a tenth preferred embodiment according to the invention, where the LED element is cut in a diagonal line thereof;

FIG. 13B is a top view showing the LED element in FIG. 13A, where the LED element is view from the light extraction side;

FIGS. 14A to 14D are cross sectional views showing a process of making the LED element of the tenth embodiment, where shown are steps until when an insulation layer 116 is formed;

FIGS. 15A to 15C are cross sectional views showing a process of making the LED element of the tenth embodiment, where shown are steps from the formation of electrodes until the completion;

FIG. 16A is a cross sectional view showing a flip-chip mounting example of the LED element of the tenth embodiment onto a mounting board;

FIG. 16B is a cross sectional view showing a flip-chip mounting example of the LED element of the tenth embodiment onto a mounting board with a concave portion;

FIG. 17A is a top view showing an LED element in an eleventh preferred embodiment according to the invention;

FIG. 17B is a cross sectional view cut along a line A-A in FIG. 17A;

FIG. 17C is a top view showing the solder connection of the LED element of the eleventh embodiment, which is viewed from the side of a sapphire substrate thereof;

FIG. 18A is a top view showing an LED element in a twelfth preferred embodiment according to the invention;

FIG. 18B is a cross sectional view cut along a line B-B in FIG. 18A;

FIG. 19 is a cop view showing an LED element in a thirteenth preferred embodiment according to the invention;

FIG. 20 is a top view showing an LED element in a fourteenth preferred embodiment according to the invention;

FIG. 21 is a cross sectional view showing a mounting structure of an LED element in a fifteenth preferred embodiment according to the invention, where the LED element is connected to a copper lead;

FIG. 22A is a cross sectional view showing a first mounting structure of an LED element in a sixteenth preferred embodiment according to the invention;

FIG. 22B is a cross sectional view showing a second mounting structure of an LED element in the sixteenth embodiment according to the invention;

FIG. 23 is a cross sectional view showing a mounting structure of an LED element in a seventeenth preferred embodiment according to the invention;

FIG. 24 is a cross sectional view showing a mounting structure of an LED element in an eighteenth preferred embodiment according to the invention;

FIG. 25A is a cross sectional view showing a large-size LED element (1 mm square) in a nineteenth preferred embodiment according to the invention; and

FIG. 25B is a top view showing the LED element in FIG. 25A, which is viewed from the side of an insulation layer formation surface thereof.

### DETAILED DESCRIPTION OP THE PREFERRED EMBODIMENTS

### First Embodiment

(Composition of LED Element 1)

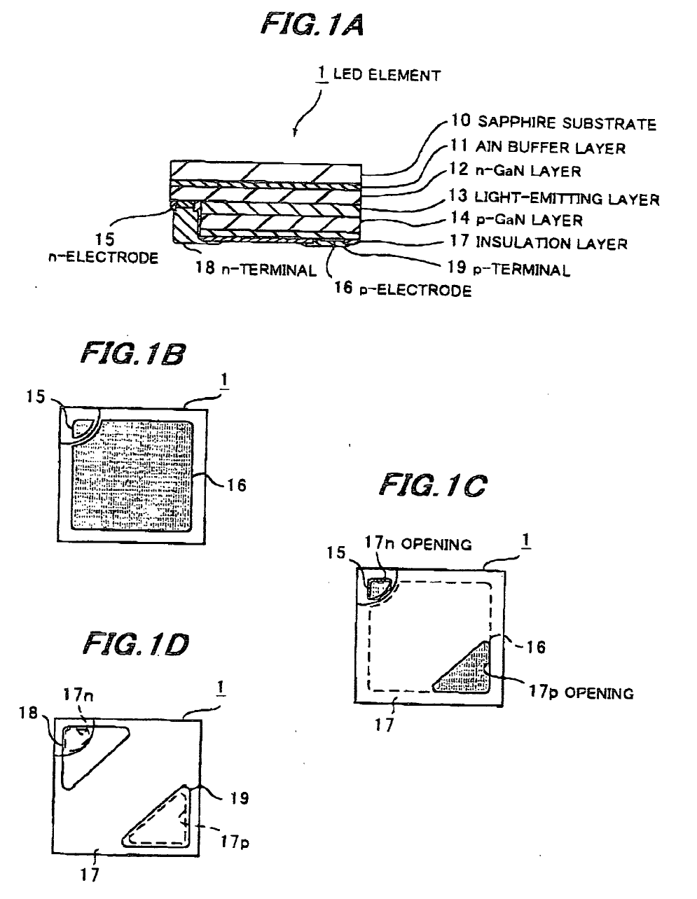

FIGS. 1A to 1D show an LED element in the first preferred embodiment according to the invention.

The LED element 1 is composed of: a sapphire substrate 10; an AlN buffer layer 11 formed on the sapphire substrate 10; an n-GaN layer 12 formed on the AlN buffer layer 11; a light-emitting layer 13 formed on the n-GaN layer 12; a p-GaN layer 14 formed on the light-emitting layer 13, the n-GaN layer 12 to the p-GaN layer 14 being of group III nitride-based compound semiconductor; an n-electrode 15 as a second electrode formed on part of the n-GaN layer 12 exposed by partially etching the p-GaN layer 14 to the n-GaN layer 12; a p-electrode 16 as a first electrode formed on the p-GaN layer 14 to supply current to the light-emitting layer 13; an insulation layer 17 of a SiO₂-based material formed to cover the electrode formation side; an n-terminal 18 electrically connected through an opening 17n provided in the insulation layer 17 to the n-electrode 15; and a p-terminal 19 electrically connected through an opening 17p provided in the insulation layer 17 to the p-electrode 16. The LED element 1 has a size of 0.3 mm×0.3 mm, which is widely prevalent.

A method of forming a group III nitride-based compound semiconductor layer is not specifically limited, and well-known metal organic chemical vapor deposition (MOCVD) method, molecular beam epitaxy (MBE) method, hydride vapor phase epitaxy (HVPE) method, sputtering method, ion plating method, cascade shower method and the like are applicable.

The LED element may have a homostructure, a heterostructure, or a double heterostructure. Furthermore, a quantum well structure (a single quantum well structure or a multiquantum well structure) is also applicable.

The p-electrode 16 is formed such that its surface occupies 60% or more of the surface of the LED element 1.

(Method of Making the LED Element 1)

The method of making the LED element 1 will be explained below.

(Step of Providing the Substrate)

First, a wafer sapphire substrate 10 is provided as an underlying substrate.

(Step of Forming the Semiconductor Layers)

Then, the AlN buffer layer 11 is formed on a surface of the sapphire substrate 10. Then, the n-GaN layer 12, the light emitting layer 13, and the p-GaN layer 14 are sequentially formed on the AlN buffer layer 11. Then, a stack portion from the p-GaN layer 14 to the n-GaN layer 12 is partially removed by etching to expose the n-GaN layer 12. The etching is conducted such that the p-GaN layer 14 has a sufficient surface area relative to the surface of the LED element 1.

(Step of Forming the Electrodes)

Then, as shown in FIG. 1B, the n-electrode 15 and the p-electrode 16 of Au are formed by deposition on the exposed surface of the n-GaN layer 12 and the surface of the p-GaN layer 14, respectively. Alternatively, the n-electrode 15 and the p-electrode 16 may be formed by other film formation method suas as sputtering.

(Step of Forming the Insulation Layer)

Then, as shown in FIG. 1C, the insulation layer 17 of the SiO₂-based material is formed to cover the electrode formation side. Then, a mask pattern corresponding to the openings 17n and 17p is formed on the insulation layer 17 and then etched to form the openings 17n and 17p in the insulation layer 17

(Step of Forming the Terminals)

Then, as shown in FIG. 1D the n-terminal 18 and the p-terminal 19 of Au are formed by deposition at the corresponding openings 17n and 17p in the insulation layer 17 Although in FIG. 1D the n-terminal 18 is shown smaller than the p-terminal 19, the n-terminal 18 and the p-terminal 19 can be formed in arbitrary form within a size not to be short-circuited each other since the electrode formation surface of the LED element 1 is covered with the insulation layer 17.

In making an LED lamp by using the LED element 1 thus fabricated, for example, a substrate of ceramics material is provided, on the surface of which a wiring pattern of copper foil is formed. The LED element 1 is positioned on the wiring pattern of the substrate and flip-chip mounted by the reflowing of solder. Then, it is integrally sealed with a seal material such as epoxy resin and glass material to have the packaged LED lamp.

(Operation of the LED Element 1)

When the LED lamp thus made is supplied with power by connecting the wiring pattern on the substrate to a power supply (not shown), a forward voltage is applied through the n-terminal 18 and the p-terminal 19 to the n-electrode 15 and the p-electrode 16. Thereby, radiative recombination of hole and electron occurs in the light-emitting layer 13 and blue light is emitted according to the form of the p-electrode 16 as shown in FIG. 1B. Blue light irradiated to the n-GaN layer 12 side is externally radiated passing through the sapphire substrate 10. Blue light irradiated to the p-GaN layer 14 side is reflected on the p-electrode 16 back to the light-emitting layer 13 and externally radiated passing through the sapphire substrate 10 as well

(Effects of the First Embodiment)

The effects of the first embodiment are as follows.
(1) Since the LED element 1 is at the electrode formation surface provided with the n-terminal 18 and the p-terminal 19 of Au to have an external connection through the insulation layer 17, the n-electrode 15 and the p-electrode 16 can be formed in arbitrary form without being limited to an electrode form needed to secure the mounting property of the LED element 1. Thus, the p-electrode 16 can be designed considering the emission form and thereby the emission area can be increased. Therefore, even when current is supplied according to an increase in the emission area, the current density in the light-emitting layer can be kept equal. As a result, the amount of emitted light can be increased.
(2) In the conventional LED element, since there was a large nonradiative portion in area ratio, symmetry in emission must be significantly broken. However, in the first embodiment, since the nonradiative area is reduced relative to the emission area of the LED element, blue light can be uniformly radiated from the entire emission surface of the LED element 1 without unevenness in light distribution.
(3) Since the emission surface area is increased relative to the emission area of the LED element, the current density in the light-emitting layer can be reduced even in the same current supply as the conventional LED element. Therefore, the thermal localization in the LED element 1 can be prevented. Thereby, the emission efficiency can be kept even when it is used for long hours.
(4) Since the irregularity in emission form can be prevented, when it is used for an LED lamp with a converging optical system, the convergence performance can be enhanced without deforming the image of light source projected and therefore a natural emission pattern can be obtained.
(5) The n-terminal 18 and the p-terminal 19 can be formed with a size and a distance not dependent on the size of the n-electrode 15 and the p-electrode 16, Therefore, it can be mounted by the reflowing of solder. Thus, the performance in mounting and heat radiation can be enhanced.

In the first embodiment, the electrical bonding to the n-terminal 18 and the p-terminal 19 can be conducted using Au bumps when the LED element 1 is mounted.

The composition of the LED element 1 is not limited to the blue LED element of group III nitride-based compound semiconductor. The LED element may emit light in other emission color and may be of another material.

Although in the first embodiment the LED element 1 is 0.3 mm×0.3 mm in size, it can be 0.2 mm×0.2 mm or smaller in size while securing an emission area. Thus, the LED element 1 can be realized in a size never before developed due to the limitation of the n-electrode area.

Also, the LED element 1 can have an elongated size such as 0.1 mm×0.3 mm for a practical use. The LED element 1 thus formed can increase a coupling efficiency to a thin-type light guiding plate.

### Second Embodiment

(Composition of LED Element 1)

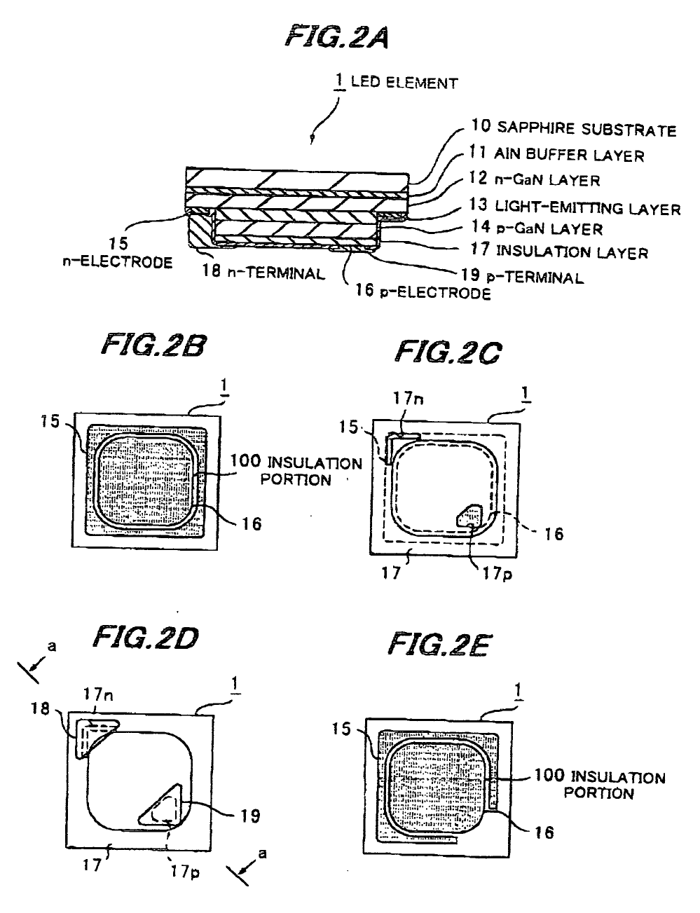

FIGS. 2A to 2D show an LED element in the second preferred embodiment according to the invention.

Herein, like components are indicated by the same numerals as used in the first embodiment.

The flip-chip type LED element 1 is different from the first embodiment in that, as shown in FIG. 2A, the p-GaN layer 14 is disposed like an island at the center of the LED element 1, the p-electrode 16 is formed thereon, and the n-electrode 15 is disposed circularly around the p-electrode 16.

The n-electrode 15 is about 10 μm in line width of narrowest portion and about 350 μm in line width of widest portion. The p-electrode 16 is, as shown in FIG. 2B, shaped like a square with rounded corners, and a predetermined distance separated through an insulation portion 100 from the n-electrode 15 which circularly surrounds the p-electrode 16. The predetermined distance is preferably such a minimum one that can prevent the light leakage from the GaN layer and the short-circuiting.

The insulation layer 17 is, as shown in FIG. 2C, formed depending on the disposition of the n-electrode 15 and the p-electrode 16. Although in FIG. 2C, the n-electrode 15 and the p-electrode 16 are disposed diagonally at the bottom of the LED element 1, they may be in parallel disposed a predetermined distance separated each other.

The n-terminal 18 and the p-terminal 19 are, as shown in FIG. 2D, disposed to cover the openings 17n, 17P. Thereby, they are electrically connected to the n-electrode 15 and the p-electrode 16 (though not shown in FIG. 2D) covered by the insulation layer 17.

### Effects of the Second Embodiment

The effects of the second embodiment are as follows.
(1) The p-GaN layer 14 is disposed like an island at the center of the LED element 1, the p-electrode 16 is formed thereon, and the n-electrode 15 is disposed circularly around the p-electrode 16. Thus, the emission portion can be disposed at the center of the LED element 1. Since electros are uniformly supplied from all regions of the p-GaN layer 14, a uniform emission can be generated in the light-emitting layer 33 under the p-electrode 16. Therefore, uniform blue light can be externally radiated from the LED element 1 to reduce unevenness in light distribution.
(2) Since the n-electrode 15 is circularly disposed around the p-electrode 16, heat of the n-electrode 15 can be dispersed widely to the LED element 1 to stabilize the light output characteristics. Further, due to the enhancement in thermal dispersion property, the heat radiation property can be improved to prevent the overheating of the LED element 1.
(3) Since the light-emitting layer 13 is formed symmetrical, a natural emission pattern can be obtained even when the LED element 1 is used in combination with the convergence optical system.

Meanwhile, as shown in FIG. 2E, the n-electrode 15 is not always formed perfectly around the p-electrode 16. When it is formed substantially around the p-electrode 16, the same effects can be obtained.

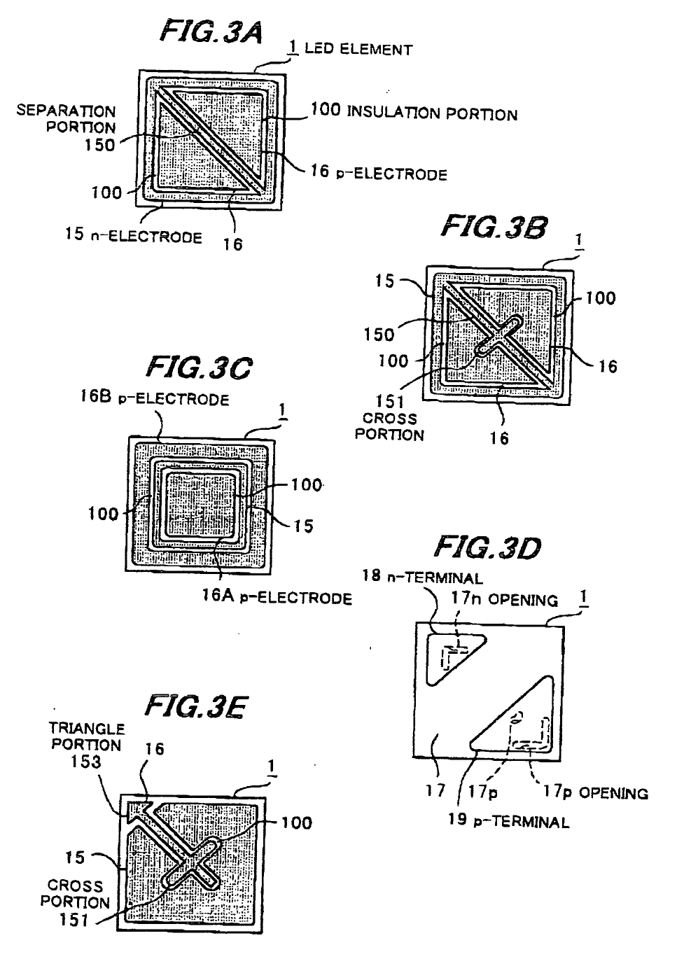

FIGS. 3A to 3E are top views showing modifications of the n-electrode and the p-electrode in the LED element of the second embodiment.

(Modification 1 of Electrode Form)

As shown in FIG. 3A, the n-electrode 15 may have a separation portion 150 that diagonally separates the p-electrode 16.

In modification 1, since the formation region of the p-electrode 16 is separated into two parts, current can be uniformly and rapidly spread and thereby good emission characteristics can be obtained under the p-electrode 16

(Modification 2 of Electrode Form)

As shown in FIG. 3B, the n-electrode 15 may have a cross portion 151 at the center of the separation portion 150.

In modification 2, since the cross portion 151 is formed while the formation region of the p-electrode 16 is separated into two parts by the separation portion 150, current can be further uniformly and rapidly spread and thereby good emission characteristics can be obtained under the p-electrode 16.

(Modification 3 of Electrode Form)

As shown in FIG. 3C, a p-electrode 16A may be formed at the center of the surface of the LED element 1 surrounded by the n-electrode 15 and a p-electrode 16B may be formed around the n-electrode 15.

FIG. 3D shows the n-terminal 18 and the p-terminal 19 formed on the insulation layer 17. The insulation layer 17 is formed on the surface of the n-electrode 15 and the p-electrodes 16A, 16B as shown in FIG. 3C while having the openings 17n, 17p. The n-terminal 18 and the p-terminal 19 are formed triangular in surface form while being partially embedded in the openings 17n, 17p. The p-terminal 19 is embedded in the two openings 17p, 17p and thereby electrically connected to the p-electrodes 16A, 16B.

In modification 3, since the p-electrodes 16A, 16B are disposed inside and outside of the n-electrode 15, a good current spreading property can be obtained to allow the good emission characteristics of the LED element 1 while reducing the area of the n-electrode 15.

(Modification 4 of Electrode Form)

As shown in FIG. 3E, the n-electrode 15 may have a triangle portion 153 formed at a corner of the surface of the LED element 1 while the n-electrode 15 has the cross portion 151 in the region of the p-electrode 16 to connect the triangle portion 153.

In modification 4, since the n-electrode 15 has the cross portion 151 and the triangle portion 153 in the region of the p-electrode 16 without surrounding the p-electrode 16, the p-electrode 16 can have an increased area. Thereby, the emission characteristics can be enhanced while preventing unevenness in light distribution.

(Modification of the Insulation Layer 17)

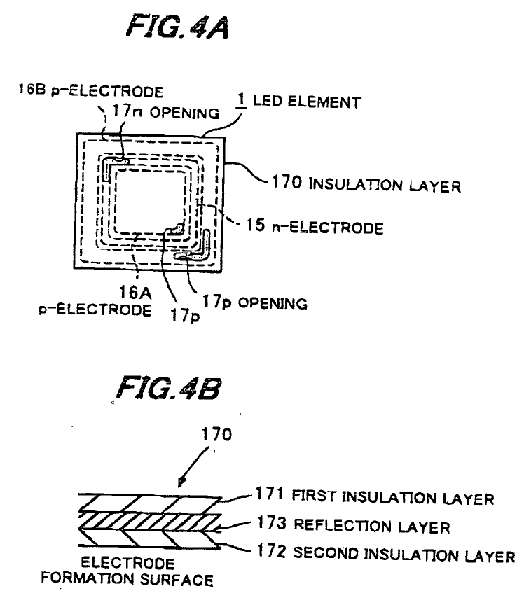

FIGS. 4A and 4B show a modification of the insulation layer 17.

A modified insulation layer 170 is composed of a first insulation layer 171, a second insulation layer 172, and a reflection layer 173 formed sandwiched by the first and the second insulation layers 171 and 172. The reflection layer 173 is made of aluminum (Al) by deposition. The insulation layer 170 is provided with openings 17n, 17P to connect the underlying n-electrode 15 and p-electrode 16 with the n-terminal and the p-terminal 19 (not shown).

Except the openings 17n, 17P, the reflection layer 173 is formed as shown in FIG. 4B. Thereby, light can be prevented from leaking in the opposite direction of the substrate through a gap between the n-electrode 15 and the p-electrode 16.

The reflection layer 173 may be made of silver (Ag) or rhodium (Rh) instead of aluminum (Al).

In this modification, since the leakage of light through the gap between the electrodes can be prevented, the brightness of the LED element 1 can be enhanced even when the n-electrode 15 is formed in the region of the p-electrode 16.

Although a bonding pad conventionally needs to have a bonding area of about φ100 μm, it may be a pattern (in arbitrary form) narrower than this area. Especially, it is effective that it has a line width of 50 μm or less, further 25 μm or less, This is because the bonding pad needed to bond a wire or bump affects on current supplied to the LED element 1. In general, a wire of φ25 μm or so is used and the bonding pad therefor needs an area twice the wire diameter. It is not effective that the bonding area is smaller than the wire diameter.

In the invention, if the n-electrode 15 is in line width narrower than the bonding pad needed conventionally as mentioned above, the effects abovementioned can be obtained. Although the n-electrode 15 is generally a narrow line of 50 μm or less, it is not limited to this size in a large current LED and may be a narrow line with a width narrower than the corresponding bonding pad.

Further, since the same effects can be obtained by substantially surrounding the p-electrode 16 as shown in FIG. 2E, the n-electrode 15 is not always formed perfectly around the p-electrode 16.

If the improvement of light distribution is desired primarily, the light-emitting layer 13 may be formed circular etc. In this case, there is a certain space at the diagonal position of the surface of the LED element 1. Therefore, the n-electrode 15 is not always formed a narrow line pattern and the terminal may be formed without forming the insulation layer 17.

### Third Embodiment

(Composition of LED Element 1)

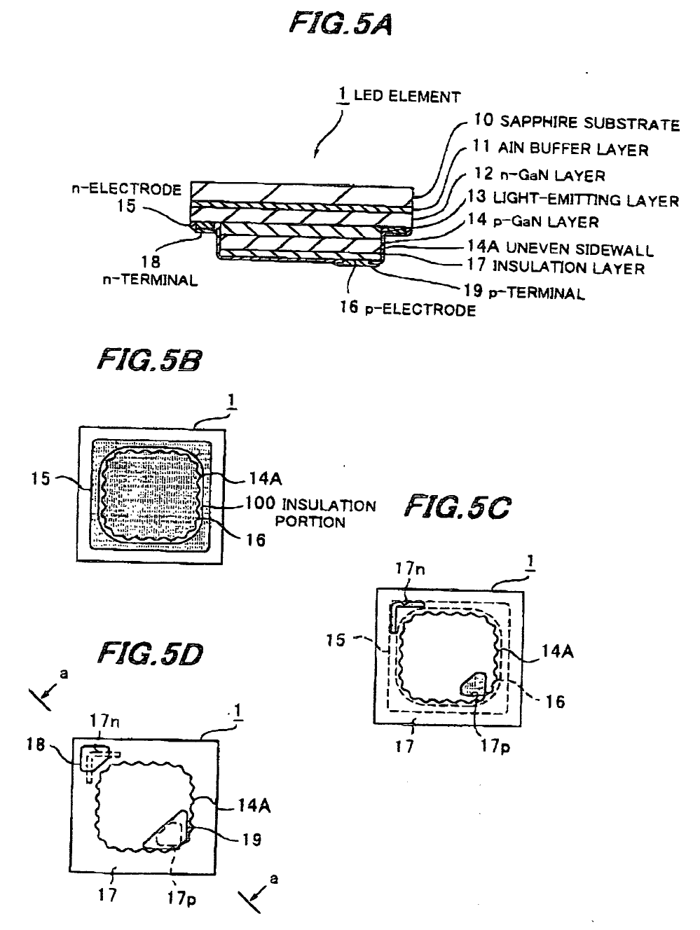

FIGS. 5A to 5D show an LED element in the third preferred embodiment according to the invention.

The flip-chip type LED element 1 is different from the first embodiment in that, as shown in FIG. 5A, the p-GaN layer 14 is disposed like an island at the center of the LED element 1, the p-electrode 16 is formed thereon, the n-electrode 15 is disposed circularly around the p-electrode 16, and the p-GaN layer 14 is provided with an uneven sidewall 14A formed uneven at the side thereof.

The uneven sidewall 14A is formed by partially removing the p-GaN layer 14 to the n-GaN layer 12 by etching to expose the n-GaN layer 12. It may be formed by another process such as cutting.

### Effects of the Third Embodiment

In the third embodiment, since the p-GaN layer 14 is formed like an island at the center of the LED element 1 and the uneven sidewall 14A is formed around the p-GaN layer 14, in addition to the effects of the second embodiment, it is easy to extract light (herein called intra-layer confined light) confined in the light-emitting layer 13. Thus, the external radiation efficiency can be enhanced.

Although in FIGS. 5B to 5D the uneven surface is illustrated with exaggeration, it is desirable that a fine uneven surface is made to secure a larger surface area of the p-GaN layer 14. Thus, the fineness of the uneven surface may be in the range of an emission wavelength and an optimum design in light extraction can be made according to a refractive index of the material, the layer composition etc.

### Fourth Embodiment

(Composition of LED Element 1)

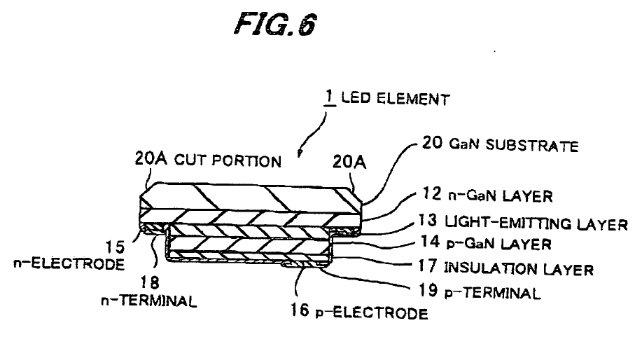

FIG. 6 is a cross sectional view showing an LED element in the fourth preferred embodiment according to the invention.

The flip-chip type LED element 1 is different from the second embodiment in that a GaN substrate 20 is used in place of the sapphire substrate 10 and is provided with cut portions 20A being 45 degrees cut off at the corner of the light extraction surface of the LED element 1.

### Effects of the Fourth Embodiment

In the fourth embodiment, since the GaN substrate 20 is used as an underlying substrate, the group III nitride-based compound semiconductor layer has a refractive index equal to the GaN substrate 20. Therefore, blue light emitted from the light-emitting layer 13 can reach the light extraction surface of the GaN substrate 20 instead of being totally reflected on the interface of the group III nitride-based compound semiconductor layer and the GaN substrate 20. Further, since the GaN substrate 20 is provided with the cut portions 20A at the corner of the light extraction surface, the light extraction efficiency can be enhanced to efficiently extract blue light.

### Fifth Embodiment

(Composition of LED Element 1)

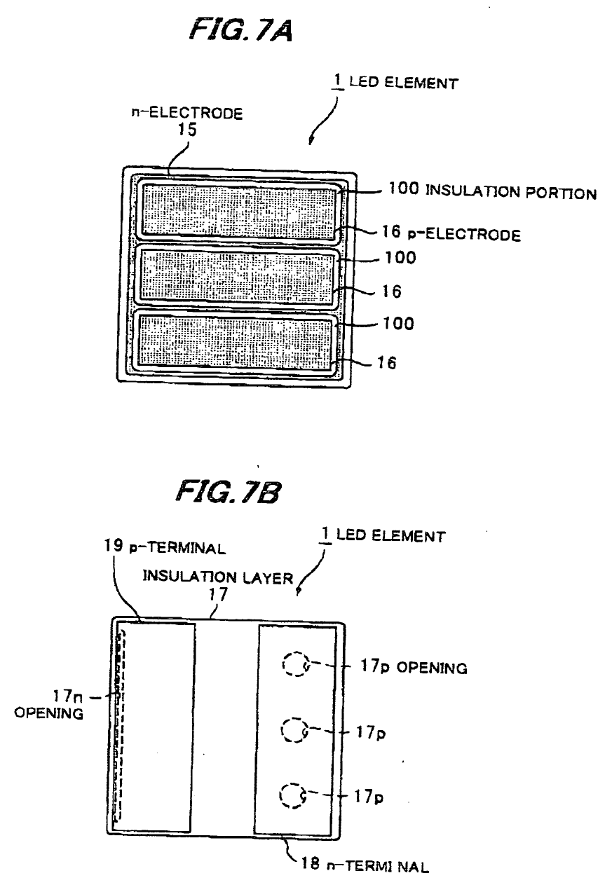

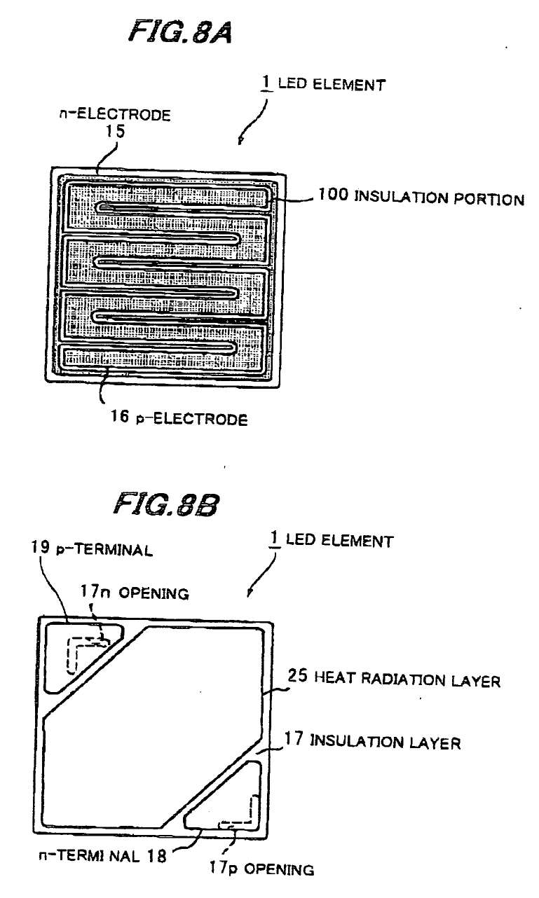

FIGS. 7A and 7B show an LED element in the fifth preferred embodiment according to the invention.

The flip-chip type LED element 1 is formed a large size (1 mm×1 mm), and as shown in FIG. 7A it is composed of the p-electrodes 16 formed rectangular and disposed in parallel and the n-electrode 15 formed to surround the p-electrodes 16 Further, as shown in FIG. 7B, the insulation layer 17 is provided with an opening 17n formed linearly therein corresponding to the n-electrode 15 and multiple openings 17p formed circular therein corresponding to the p-electrode 16. The n-electrode 15 and the p-electrode 16 are electrically connected through the openings 17n, 17p to the n-terminal 18 and the p-terminal 19, respectively.

As shown in FIG. 7B, the n-terminal 18 and the p-terminal 19 are formed rectangular in a predetermined width while being disposed along the opposite sides of the LED element 1.

### Effects of the Fifth Embodiment

In the fifth embodiment, since the emission area is increased relative to the surface area of the LED element 1 in the large size LED 1, the brightness can be enhanced without reducing the heat radiation property.

The LED element 1 can be mounted through a solder other than Au. In using the solder, since a surface heat radiation path is formed through the solder, unevenness in temperature can be prevented in the LED element 1.

Due to the large size, the design freedom of electrode formation can be enhanced.

Further, the productivity can be enhanced since the p-electrode 16 and the n-electrode 15 have the rectangular shape easy to form.

In the fifth embodiment, by using the insulation layer 170 as explained earlier instead of the insulation layer 17, light can be prevented from leaking through a gap between the n-electrode 15 and the p-electrode 16. Thereby, the brightness can be further enhanced.

### Sixth Embodiment

(Composition of LED Element 1)

FIGS. 8A and 8B show an LED element in the sixth preferred embodiment according to the invention.

The flip-chip type LED element 1 is formed a large size (1 mm×1 mm), and as shown in FIG. 8A it has an electrode form that the formation area of the p-electrode 16 is arranged like a zigzag to the formation area of the n-electrode 15. Further, as shown in FIG. 8B, the insulation layer 17 is provided with openings 17n, 17p, through which the n-electrode 15 and the p-electrode 16 are electrically connected to the n-terminal 18 and the p-terminal 19, respectively.

The n-terminal 18 and the p-terminal 19 are diagonally disposed at the corner of the LED element 1, and a heat radiation layer 25 of Rh—Au is formed a thin film therebetween.

### Effects of the Sixth Embodiment

In the sixth embodiment, like the fifth embodiment, the emission area can be increased relative to the surface of the LED element 1. Further, since the heat radiation layer 25 with a good heat radiation property is formed on the surface of the is insulation layer 17, the LED element 1 can be stably operated even in large current or long operation. Since the heat radiation layer 25 can reflect light leaked through a gap between the n-electrode 15 and the p-electrode 16, loss of emitted light can be reduced.

In place of the insulation layer 17, the insulation layer 170 as explained earlier may be used. Thereby, light can be prevented from leaking through a gap between the heat radiation layer and the n-electrode 15 or the p-electrode 16. Thereby, the brightness can be further enhanced.

### Seventh Embodiment

(Composition of LED Element 1)

FIGS. 9A and 9B show an LED element in the seventh preferred embodiment according to the invention.

The flip-chip type LED element 1 is formed a large size (1 mm×1 mm), and as shown in FIG. 9A it has an electrode form that the multiple p-electrodes 16 are formed hexagonal or semi-hexagonal and arranged zigzag and the n-electrode 15 is formed around the p-electrode 16. Further, as shown in FIG. 9B, the insulation layer 17 is provided with openings 17n (in trident form), 17p (in circular form), through which the n-electrode 15 and the p-electrode 16 are electrically connected to the n-terminal 18 and the p-terminal 19, respectively.

### Effects of the Seventh Embodiment

In the seventh embodiment, since the hexagonal emission region is formed by the electrode form with the hexagonal p-electrode 16 surrounded by the n-electrode 15, the light-emitting layer 13 under the p-electrode 16 can have a high emission intensity. Further, due to the integration of the emission regions with a high emission intensity, the brightness can be enhanced at the entire surface of the LED element 1.

### Eighth Embodiment

(Composition of LED Element 1)

FIGS. 10A and 10B show an LED element in the eighth preferred embodiment according to the invention.

The flip-chip type LED element 1 is formed a large size (1 mm×1 mm), and as shown in FIG. 10A it has an electrode form that the cross-shaped n-electrode 15 is formed in the formation area of the p-electrode 16. Further, as shown in FIG. 10B, the insulation layer 17 is provided with openings 17n, 17p, through which the n-electrode 15 and the p-electrode 16 are electrically connected to the n-terminal 18 and the p-terminal 19, respectively.

The p-terminal 19 is formed such that its surface area is increased relative to the surface of the LED element 1 to enhance the radiation of heat generated in operating the LED element 1. Also, it is formed to cover most of the n-electrode 15 since the n-electrode 15 generates relatively much heat.

### Effects of the Eighth Embodiment

In the eighth embodiment, since the surface area of the p-electrode 16 is relatively increased by disposing the cross-shaped n-electrode 15 in the formation area of the p-electrode 16, unevenness in temperature can be prevented in the LED element 1. Further, unevenness in light distribution can be reduced, design freedom in electrode formation can be enhanced, and the brightness can be enhanced.

### Ninth Embodiment

(Composition of LED Element 1)

FIGS. 11A and 11B show an LED element in the ninth preferred embodiment according to the invention.

The flip-chip type LED element 1 is formed a large size (1 mm×1 mm)), and as shown in FIG. 11A it has an electrode form that an inverted E-shaped n-electrode 15 is formed in the formation area of the p-electrode 16, a linear n-electrode 15 is formed outside of the p-electrode 16, and the inverted E-shaped n-electrode 15 is connected to the linear n-electrode 15. Further, as shown in FIG. 11B, the insulation layer 17 is provided with openings 17n (in leaner form), 17p (in circular form), through which the n-electrode 15 and the p-electrode 16 are electrically connected to the n-terminal 18 and the p-terminal 19, respectively.

The n-terminal 18 is formed to cover the formation area of the n-electrode 15 so as to reflect light leaked through a gap between the n-electrode 15 and the p-electrode 16 back to the semiconductor layer side.

### Effects of the Ninth Embodiment

In the ninth embodiment, the emission area can be increased relative to the surface of the LED element 1. Further, a good emission property can be obtained while reducing the relative area of the n-electrode 15 to the p-electrode 16.

Also in the ninth embodiment, in place of the insulation layer 17, the insulation layer 170 as explained earlier may be used. Thereby, light can be prevented from leaking through a gap between the heat radiation layer and the n-electrode 15 or the p-electrode 16. Thereby, the brightness can be further enhanced.

Since the resistivity of a p-layer is high in GaN-based semiconductors, the emission area is located substantially under or over a p-electrode. Therefore, the electrode formed as descried above is particularly effective. Alternatively, the electrode formation may be used for another semiconductor material. In this case, the electrode pattern may be reversed depending on the level of resistivity.

### Tenth Embodiment

(Composition of LED Element 1)

FIGS. 13A and 13B show an LED element in the tenth preferred embodiment according to the invention.

As shown in FIG. 13A, the LED element 101 is composed of: a sapphire substrate 110; an AlN buffer layer 111 formed on the sapphire substrate 110; an n-GaN layer 112 formed on the AlN buffer layer 111; a light-emitting layer 113 formed on the n-GaN layer 112; a p-GaN layer 114 formed on the light-emitting layer 113, the n-GaN layer 112 to the p-GaN layer 114 being of group III nitride-based compound semiconductor and composing a GaN-based semiconductor layer 200; a p-contact electrode 115 formed on the p-GaN layer 114 to spread current into the p-GaN layer 114; a transparent insulation layer 116 formed on the side of the GaN-based semiconductor layer 200 and on the p-contact electrode 115, an n-external electrode 117 formed on part of the n-GaN layer 112 exposed by partially etching the p-GaN layer 114 to the n-GaN layer 112 and on the side of the insulation layer 116; a p-external electrode 118 formed on the side of the insulation layer 116 in contact with the p-contact electrode 115; and a transparent insulation layer 119 formed to cover the element surface between the n-external electrode 117 and the p-external electrode 118.

Herein, the GaN-based semiconductor layer 200 comprises a stack portion from the n-GaN layer 112 to the p-GaN layer 114. Light emitted from the light-emitting layer 113 of the LED element 101 has an emission wavelength of 460 nm.

A method of forming a group III nitride-based compound semiconductor layer is not specifically limited, and well-known metal organic chemical vapor deposition (MOCVD) method, molecular beam epitaxy (MBE) method, hydride vapor phase epitaxy (HVPE) method, sputtering method, ion plating method, cascade shower method and the like are applicable.

The LED element may have a homostructure, a heterostructure, or a double heterostructure. Furthermore, a quantum well structure (a single quantum well structure or a multiquantum well structure) is also applicable.

The p-contact electrode 115 serves to spread current into the p-GaN layer 114 and to give a good electrical connection with an external member or device. It is made of rhodium (Rh) with a light reflection property. The p-contact electrode 115 may be made of transparent ITO (indium tin oxide) or ZnO or a transparent material such as Au/Co, Ni/Ti if it can be in ohmic contact with the p-GaN layer 114.

The insulation layer 116 is made of SiO₂ and disposed to cover the side of the GaN-based semiconductor layer 200 to prevent the short-circuiting of the n-external electrode 117 and the p-external electrode 118 with the GaN-based semiconductor layer 200. It may be made of another insulative material such as SiN instead of SiO₂.

The n-external electrode 117 is made of V/Al, and the p-external electrode 118 is made of Ti. These external electrodes are formed such that they are exposed on an element periphery ranging from the side of the element to an edge of the surface of the insulation layer 119 so as to allow the electrical bonding at the side of the element and the surface mounting at the surface side of the p-contact electrode 115. Herein, the element periphery comprises the side of the LED element 101 and an edge of the surface of the insulation layer 119 as shown in FIG. 13A. As shown in FIG. 13B, the n-external electrode 117 ranges over the entire length of two adjacent sides and the p-external electrode 118 is formed part of two sides opposed to the two sides of the n-external electrode 117. The p-external electrode 118 has a formation region smaller than the n-external electrode 117. The electrode surface may be solder-plated.

(Method of Making the LED Element 101)

FIGS. 14A to 14D are cross sectional views showing a process of making the LED element of the tenth embodiment, where shown are steps until when the insulation layer 116 is formed at the side of the LED element 101.

Hereinafter, for the sake of explanation, only part of a wafer corresponding to the LED element 101 is illustrated in the drawings although, in fact, the wafer sapphire substrate 110 is used to grow the semiconductor layer thereon and then the wafer with the semiconductor layer is diced to obtain the LED element 101.

(Step of Forming the GaN-based Semiconductor Layer 200)

At first, as shown in FIG. 14A, the AlN buffer layer 111, the GaN-based semiconductor layer 200 and the p-contact electrode 115 are formed on the wafer sapphire substrate 110 by MOCVD.

(First Etching Step)

Then, as shown in FIG. 14B, the GaN-based semiconductor layer 200 is dry-etched to remove a stack portion from the surface of the GaN-based semiconductor layer 200 to the n-GaN layer 112, where the stack portion corresponds to a region to form the n-external electrode 117 and the p-external electrode 118. Thereby, an exposed portion 112A is formed at the side of the GaN-based semiconductor layer 200. Alternatively, the p-contact electrode 115 may be formed placing a photoresist on the semiconductor layer after the exposed portion 112A is formed, and then the photoresist can removed

(Step of Forming the Insulation Layer 116)

Then, as shown in FIG. 14C, the insulation layer 116 is formed by deposition on the GaN-based semiconductor layer 200 after the dry etching.

(Second Etching Step)

Then, as shown in FIG. 14D, a photoresist is placed on the GaN-based semiconductor layer 200 with the insulation layer 116 formed thereon, and then the insulation layer 116 is partially etched except its portion corresponding to the side of the GaN-based semiconductor layer 200. Thereby, part of the exposed portion 112A and the p-contact electrode 115 are exposed.

FIGS. 15A to 15C are cross sectional views showing a process of making the LED element of the tenth embodiment, where shown are steps from the formation of electrodes until the completion.

(Step of Forming the External Electrodes 117, 118)

As shown in FIG. 15A, in the electrode formation process, the n-external electrode 117 of V/Al is formed by deposition at the exposed portion 112A on the n-external electrode 117 side. Then, the p-external electrode 118 of Ti is formed by deposition at the exposed portion 112A on the p-external electrode 118 side.

The n-external electrode 117 may be made of a material that can be in ohmic contact with the n-GaN layer 112, for example, it may be of Ti other than V/Al. The p-external electrode 118 may be made of a material that can be electrically connected with the p-contact electrode 115, for example, it may be of Al other than Ti.

Further, both of the n-external electrode 117 and the p-external electrode 118 may be of Ti. In this case, the n-external electrode 117 and the p-external electrode 116 can be formed together in the same step and thus the manufacturing step can be simplified.

(Step of Forming the Insulation Layer 119)

Then, as shown in FIG. 5B, the insulation layer 119 of SiO₂ is formed by deposition over the upper surface of the GaN-based semiconductor layer 200 including the electrode 115 and the formation region of the n-external electrode 117 and the p-external electrode 118.

(Third Etching Step)

Then, as shown in FIG. 15C, the insulation layer 119 is etched placing a photoresist on the GaN-based semiconductor layer 200 and then the photoresist is removed. Thereby, the insulation layer 119 is left except part on the n-external electrode 117 and the p-external electrode 118 at the element periphery such that it can prevent the short-circuiting of the n-external electrode 117 and the p-external electrode 118 and protect them.

(Dicing Step)

Then, the wafer composed of the GaN-based semiconductor layer 200 with the n-external electrode 117 and the p-external electrode 118 formed thereon and the sapphire substrate 110 is cut into a given element size by a dicer (not shown). As a result, the LED element 101 as shown in FIG. 15C can be obtained. The cutting of the wafer can be conducted by another process such as scribing instead of the dicing.

(Mounting of the LED Element 101)

FIG. 16A is a cross sectional view showing a flip-chip mounting example of the LED element of the tenth embodiment onto a mounting board.

As shown in FIG. 16A, the LED element 101 fabricated as described above is mounted being bonded through an epoxy insulative adhesive 141 onto the surface of a ceramics board 123 with a wiring pattern 122 formed thereon. The n-external electrode 117 and the p-external electrode 118 are reflow-bonded to the wiring pattern 122 through a solder 120A.

The insulative adhesive 141 may be of another material if it has a good thermal conductivity, for example, it may a paste with no adhesivity such that the LED element 101 can be in close contact with the board 123 in sheet form. It is more desirable that 141 is made of a material with high heat resistance and good adhesivity.

If the insulation to the wiring pattern 122 can be secured, the board 123 may be a conductive board that a metal material such as Cu and Al with a high heat conductivity is subjected to insulation treatment, instead of the abovementioned insulative board such as a flexible board of ceramics, glass epoxy, polyimide and conductive foil.

If no short-circuiting of the n-external electrode 117 and the p-external electrode 118 is generated, the insulative adhesive 141 may be replaced by a conductive material to bond the LED element 101 onto the board 123. Such a material can be a conductive paste of silicone resin containing a filler such as Au, Cu and Al.

The solder 120A may be replaced by a conductive adhesive such as an epoxy resin containing Ag paste or a conductive filler such as Au, Cu and Al so as to allow the electrical connection of the n-external electrode 117 and the p-external electrode 118 with the wiring pattern 122.

FIG. 16B is a cross sectional view showing a flip-chip mounting example of the LED element of the tenth embodiment onto a mounting board with a concave portion.

As shown in FIG. 16B, a board 123 with the concave portion 123A for positioning the element may be used such that part of the p-contact electrode 115 is inserted into the concave portion 123A. The concave portion 123A is coated with the insulative adhesive 141 to allow the bonding of the part of the p-contact electrode 115 of the LED element 101. Like the manner as shown in FIG. 16A, the n-external electrode 117 and the p-external electrode 118 are reflow-bonded to the wiring pattern 122 through the solder 120A.

(Operation of the LED Element 101)

When power is supplied connecting the wiring pattern 122 on the substrate to a power supply (not shown), a forward voltage is applied through the n-external electrode 117 and the p-external electrode 118 of the LED element 101 to the light-emitting layer 113. Thereby, radiative recombination of hole and electron occurs in the light-emitting layer 113 and blue light is emitted. Blue light irradiated to the sapphire substrate 110 side is externally radiated passing through the sapphire substrate 110. Heat generated during the operation of the LED element 101 is radiated through the insulative adhesive 141 to the board 123.

### Effects of the Tenth Embodiment

The effects of the tenth embodiment are as follows.
(1) Since the LED element 101 is fabricated with the n-external electrode 117 and the p-external electrode 118 formed around the light-emitting layer 113 based on the manufacturing process for the semiconductor LED by using the wafer sapphire substrate 110, the LED element 101 can be easily made in a lot and in mass production by using the known apparatus and method.
(2) Since the n-external electrode 117 and the p-external electrode 118 are formed around the light-emitting layer 113, not on the light extraction surface, while partially removing the sides of the GaN-based semiconductor layer 200, light emitted from the light-emitting layer 113 can be prevented from being blocked by the n-external electrode 117 and the p-external electrode 118. Further, due to the disposition of the external electrodes, the emission area of the light-emitting layer 113 can be increased in the same element size and the emission intensity can be enhanced. Thus, the LED element 101 can have a good light extraction efficiency and a high brightness.
(3) The electrical connection with the wiring pattern 122 etc. can be made in any of flip-chip mounting or face-up mounting. Namely, the type of mounting can be chosen according to use. For example, another type of mounting other than the above types can be conducted in which one side of the LED element 101 is used in electrical or mechanical bonding. Thus, various types of mounting can be offered.
(4) Since the nonradiative portion such as a wire bonding space and an n-electrode bump space can be eliminated or reduced, even the small size LED element 101 can have a sufficient ratio of emission area/LED surface area. Therefore, a further small LED element 101 can be realized which has an electrode interval near to the element width. For example, even an LED element 101 of 0.1 mm square can have a practical emission area. If n-and p-electrodes for Au stud bump mounting are disposed under the LED element 101, an electrode with a diameter of about 0.1 mm needs to be provided correspondingly. Thus, it is difficult to make an LED element 101 of less than 0.1×0.2 mm².
(5) Since the n-external electrode 117 and the p-external electrode 118 are continuously formed over the two sides of the element, the bonding area of the solder 120A for reflow bonding can be increased, thereby offering a stable mounting and a good heat radiation property. Further, the secure mounting can be obtained without requiring a high precision in positioning like the bump bonding. Meanwhile, the n-external electrode 117 and the p-external electrode 118 are not always continuously formed over the two sides, and they may be formed not continuously.
(6) In the flip-chip bonding of the LED element 101, the surface of the GaN-based semiconductor layer 200 is face-bonded to the board 123, and the n-external electrode 117 and the p-external electrode 118 are electrically connected through the solder 120A. Therefore, the bonding strength can be enhanced. The heat radiation property can be improved such that heat is radiated from the GaN-based semiconductor layer 200 to the board 123 without passing through the sapphire substrate 110. Further, the reliability can be improved such that the seal resin does not exist at the bonding interface of the LED element 101 and, therefore, the separation of bonded portion does not occur due to thermal expansion.

Although in the tenth embodiment the blue LED element 101 of the group III nitride-based compound semiconductor is explained, the invention is not limited to the blue LED element 101 and may be applied to another emission color LED. Further, the LED element 101 may be made of another material instead of the group III nitride-based compound semiconductor.

Alternatively, a GaN substrate may be used in place of the sapphire substrate 110 as an underlying substrate to grow a group III nitride-based compound semiconductor layer thereon.

Even when the LED element 101 is flip-chip mounted using the p-contact electrode 115 as the mounting face as shown in FIG. 16A, light can be extracted to a direction of the board 123 by using the p-contact electrode 118 made of transparent ITO and the board 123 made of a transparent material such as glass.

### Eleventh Embodiment

(Composition of LED Element 101)

FIGS. 17A to 17C show an LED element in the eleventh preferred embodiment according to the invention.

The LED element 101 is composed of five emission regions disposed in the longitudinal direction as shown in FIG. 17A. It is further composed of plural n-external electrodes 117 and p-external electrodes 118. The p-external electrode 118 is, as shown in FIG. 17B, connected through an electrode connecting portion 118A to the p-contact electrode 115 made of Rh.

Also in the elongated LED element 101, the n-external electrode 117 and the p-external electrode 118 are provided at the side of the element and have a bonding width to give a sufficient bonding property. The n-external electrode 117 and the p-external electrode 118 are disposed opposed to, each other at the longer sides of the LED element 101. The n-external electrode 117 is exposed at the shorter sides of the LED element 101.

The n-external electrode 117 and the p-external electrode 118 are flip-chip bonded on a wiring pattern of a board (not shown) through a solder 120A as shown in FIG. 17C.

### Effects of the Eleventh Embodiment

In the eleventh embodiment, in addition to the effects of the tenth embodiment, the LED element 101 is suitable for a use in need of a large amount of light since it is easy to form the wiring on the LED element 101 though having the elongated structure. Also, since the n-external electrode 117 and the p-external electrode 118 are provided with a given bonding with at the side of the LED element 101, a uniform and good electrical bonding property can be obtained.

Even when the plural emission regions are provided as shown in FIG. 17A, heat can be rapidly radiated from the GaN-based semiconductor layer 200 to the mounting face (not shown) as described in the tenth embodiment. Thus, a sufficient heat radiation property can be offered even in a high-output LED element 101.

Although in the eleventh embodiment is explained the elongated LED element 101 with the five emission regions, the number, size and form of emission regions may be arbitrarily varied according to use.

The LED element 101 is not limited to a use for the flip-chip mounting, and it may be face-up mounted while making modifications that the p-contact electrode 115 is made of a transparent material such as ITO, ZnO, Au/Co and Ni/Ti and that the sapphire substrate 110 is used as the mounting face.

### Twelfth Embodiment

(Composition of LED Element 101)

FIGS. 18A and 18B show an LED element in the twelfth preferred embodiment according to the invention.

The LED element 101 is a large size (1 mm square) LED element. It is provided with an n-external electrode 117 that extends like a comb from the side of the element into the emission region and plural electrode connecting portions 118A to connect the p-contact electrode 115 and the p-external electrode 118.

Also in the twelfth embodiment, the n-external electrode 117 and the p-external electrode 118 are exposed opposite to each other at the side of the element and formed over the entire width of one side of the element.

The p-contact electrode 115 may be made of a transparent material when the LED element 101 is used to extract light from the surface of the GaN-based semiconductor layer 200. In contrast, it may be made of a reflective conductive material such as Rh other than the transparent material when the LED element 101 is used to extract light from the surface of the sapphire substrate 110.

### Effects of the Twelfth Embodiment

In the twelfth embodiment, since the n-external electrode 117 and the p-external electrode 118 are disposed at the side of the element not on the light extraction surface, the large size LED element 101 can have an increased area to extract light from the inside of the element so as to enhance the light extraction efficiency.

Since the n-external electrode 117 and the p-external electrode 118 are formed opposite to each other at the side of the element, the bonding area to the external member or device can be increased, thereby enhancing the bonding strength, the heat radiation property and the uniformity in Current spreading. Further, the LED element 101 can be securely mounted without requiring a troublesome adjustment such as positioning in the mounting as compared to an Au bump mounting.

Although in the large size LED element 101 the amount of heat generation is increased as compared to a standard size LED element, a sufficient heat radiation property can be secured since the n-external electrode 117 and the p-external electrode lie are disposed at the side of the element to be in close contact with the mounting board.

Although in the twelfth embodiment the n-external electrode 117 and the p-external electrode 118 are disposed opposite to each other at the side of the LED element 101 and formed over the entire width of the side, these electrodes may be formed in arbitrary position and size if the n-external electrode 117 and the p-external electrode 118 are exposed at the side of the LED element 101 without being short-circuited each other.

Although in the twelfth embodiment the LED element 101 is provided with the nine electrode connecting portions 118A, the number, size and form of the electrode connecting portions 118A may be arbitrarily varied according to use.

### Thirteenth Embodiment

FIG. 19 shows an LED element in the thirteenth preferred embodiment according to the invention.

The LED element 101 is formed such that the n-external electrode 117 and the p-external electrode 118 are disposed along the side of the large size LED element 101.

This structure can also enhance the bonding strength, the heat radiation property and the uniformity in current spreading as described in the twelfth embodiment.

### Fourteenth Embodiment

FIG. 20 shows an LED element in the fourteenth preferred embodiment according to the invention.

The LED element 101 is formed such that the n-external electrode 117 and the p-external electrode 118 are disposed opposite to each other at the side of the large size LED element 101 and formed extending like a comb toward the center of the LED element 101 from the side.

This structure can also enhance the bonding strength and the heat radiation property as described in the twelfth embodiment.

Further, since the n-external electrode 117 and the p-external electrode 118 are formed extending like a comb, the uniformity in current spreading can be further enhanced.

### Fifteenth Embodiment

(Mounting Structure of LED Element 101)

FIG. 21 is a cross sectional view showing a mounting structure of an LED element in the fifteenth preferred embodiment according to the invention, where the LED element 101 is connected to a copper lead 121.

The copper lead 121 is made by forming a copper alloy material into a lead form by pressing etc. It is connected to the n-external electrode 117 and the p-external electrode 118 at the side of the LED element 101 by the solder bonding with solder plating 120.

The LED element 101 is provided with the p-contact electrode 115 made of Rh so as to extract light from the surface of the sapphire substrate 110.

Although the n-GaN layer 112 is at a side thereof in face contact with the copper leads 121, 121 to supply current to the anode side and the cathode side, short-circuiting does not occur since it is not in ohmic contact with them at the contact face.

As shown in FIG. 21, one pair of the copper leads 121, 121 serve as an electrical connection and a mechanical support, and the LED element 101 is suspended supported by the copper leads 121, 121.

In order to protect the LED element 101 and the copper lead 121 and to enhance the light extraction efficiency, it is desirable that the LED element 101 and the copper lead 121 are integrally sealed with a seal resin such as epoxy resin.

The solder plating 120 may be replaced by a conductive bonding material to electrically connect the copper lead 1201 and the LED element 101. Such a conductive bonding material includes, e.g., epoxy adhesive containing Ag paste or a conductive filler.

(Operation of the LED Element 101)

When power is supplied connecting the copper lead 121 on to a power supply (not shown), a forward voltage is applied through the n-external electrode 117 and the p-external electrode 118 of the LED element 101 to the light-emitting layer 113. Thereby, radiative recombination of hole and electron occurs in the light-emitting layer 113 and blue light is emitted. Blue light irradiated to the sapphire substrate 110 side is externally radiated passing through the sapphire substrate 110. In contrast, blue light irradiated to the p-contact electrode 115 side is reflected on the p-contact electrode 115 and then externally radiated passing through the sapphire substrate 110

### Effects of the Fifteenth Embodiment

The effects of the fifteenth embodiment are as follows.
(1) Since the n-external electrode 117 and the p-external electrode 118 are disposed at the side of the LED element 101 not on the light extraction surface, another type of mounting other than face-up and flip-chip can be realized as shown in FIG. 21. Thus, the mounting structure can be low-profile and compact and the package with a seal material can be enhanced in sealability and downsized. It is more desirable that the copper lead 121 is in height lower than the LED element 101 to enhance the light extraction efficiency from the side face.
(2) Since the copper lead 121 with a good thermal conductivity is disposed at the side of the element, heat generated during the operation can be rapidly radiated through the GaN-based semiconductor layer 200 and the solder plating 120 without blocking the external radiation of emitted light of the LED element 101.

In the fifteenth embodiment the LED element 101 is provided with the p-contact electrode 115 made of Rh. However, when the p-contact electrode 115 is made of a transparent material such as ITO, light can be extracted from any of the surface of the sapphire substrate 110 and the surface of the GaN-based semiconductor layer 200.

### Sixteenth Embodiment

(Mounting Structure of LED Element 101)

FIG. 22A is a cross sectional view showing a first mounting structure of an LED element 101 in the sixteenth preferred embodiment according to the invention.

As shown in FIG. 22A, the LED element 101 is provided with the p-contact electrode 115 made of a transparent material such as ITO. The sapphire substrate 110 is at the bottom face bonded to the insulative board 123 made of Al₂O₃ through an adhesive (not shown). The n-external electrode 117 and the p-external electrode 118 are electrically connected through the solder 120A to the wiring pattern 122 formed on the surface of the board 123.

The solder 120A may be replaced by a conductive adhesive such as Ag paste and epoxy adhesive containing a conductive filler. The conductive adhesive may be transparent. For example, if a transparent epoxy resin containing a conductive filler is used, light can be extracted from the side of the LED element 101.

The board 123 may be transparent. In this case, light is can be extracted from the surface of the GaN-based semiconductor layer 200 and from the surface of the sapphire substrate 110 toward the board 123.

The board 123 may be made of a conductive material such as Cu and Al. In this case, although an insulation layer needs to be formed on the surface to prevent the short-circuiting through the board 123, it is effective to choose the conductive material to secure a heat radiation property.

FIG. 22B is a cross sectional view showing a second mounting structure of an LED element in the sixteenth embodiment according to the invention.

The second mounting structure is different from the first structure in that the LED element 101 is placed in a concave portion 123A formed in the board 123.

The concave portion 123A is provided with a slope 123B so as to have a space around the LED element 101. Since the LED element 101 is placed in the concave portion 123A, the amount of protrusion from the surface of the board 123 can be reduced. The LED element 101 is electrically connected through the solder 120A embedded in the space formed between the slope 123B and the LED element 101 to a pair of wiring patterns 122.

The board 123 in FIG. 22B may be made of a metal material with a light reflection property. In this case, although an insulation layer is formed on the surface, light irradiated to the side direction of the LED element 101 can be reflected on the reflective slope 123B so as to be extracted upward. Further, the solder 120A may be a transparent and conductive adhesive to enable the light extraction even in the electrical connection portion

### Effects of the Sixteenth Embodiment

(1) In the first mounting structure, since the electrical connection is made through the solder 120A to the n-external electrode 117 and the p-external electrode 118 formed at the side of the LED element 101, the light extraction area from the GaN-based semiconductor layer 200 can be increased. The electrical connection at the side of the element may be made through the conductive adhesive etc. instead of the solder 120A Thus, a suitable way of bonding can be chosen according to use. Further, when the board 123 is made of a transparent material, light can be extracted from the surface of the board 123.
(2) In the second mounting structure, in addition to the effects of the first mounting structure, since the LED element 101 is place in the concave portion 123A of he board 123, the LED element 101 can be easily positioned and made low-profile by reducing the amount of protrusion from the surface of the board 123. Further, since the concave portion 123A is provided with the slope 123B, light irradiated to the side direction of the LED element 101 can be reflected on the slope 123b to be extracted upward.

### Seventeenth Embodiment

(Mounting Structure of LED Element 101)

FIG. 23 is a cross sectional view showing a mounting structure of an LED element in the seventeenth preferred embodiment according to the invention.

The LED element 101 of the seventeenth embodiment is different from the LED element 101 in FIG. 16A in that the sapphire substrate 110 is lifted off.

The LED element 101 is prepared by lifting off the sapphire is substrate 110 and the AlN buffer layer 111 by irradiating laser light toward the surface of the sapphire substrate 110. Meanwhile, after the lift-off, the AlN buffer layer 111 may be left on the surface of the n-GaN layer 112. In such a case, it is desirable that the remaining AlN buffer layer 111 is removed by acid cleaning.

In operation, when power is supplied connecting the wiring pattern 122 to a power supply (not shown), a forward voltage is applied through the n-external electrode 117 and the p-external electrode 118 of the LED element 101 to the light-emitting layer 113. Thereby, radiative recombination of hole and electron occurs in the light-emitting layer 113 and blue light is emitted. Blue light irradiated to the n-GaN layer 112 is externally radiated passing through the n-GaN layer 112. In contrast, blue light irradiated to the p-contact electrode 115 is reflected on the p-contact electrode 115 made of Rh and then externally radiated passing through the n-GaN layer 112.

The p-contact electrode 115 may be made of a transparent material such as ITO if the board 123 is made of a transparent material. Thereby, light can be extracted from the bottom side of the GaN-based semiconductor layer 200.

### Effects of the Seventeenth Embodiment

In the seventeenth embodiment, light can be extracted from the n-GaN layer 112 of the flip-chip mounted LED element 101. Therefore, the intra-layer confined light being not externally radiated from the GaN-based semiconductor layer 200 can be reduced so as to enhance the external radiation efficiency.

Further, since the n-external electrode 117 and the p-external electrode 118 are disposed at the side of the LED element 101, the LED element 101 can be low profiled to meet the downsizing of a mounted object or to avoid a restriction caused by the form of a mounted object. Further, the heat radiation property through the insulation layer 119 to the board 123 can be enhanced.

In view of the protection of the LED element 101, it is desirable that the n-GaN layer 112 is covered with a transparent material or sealed with a seal material such as epoxy resin as well as the wiring pattern 122 and the board 123.

The n-GaN layer 112 may be provided with an uneven surface to reduce the intra-layer confined light to enhance the external radiation efficiency.

### Eighteenth Embodiment

(Mounting Structure of LED Element 101)

FIG. 24 is a cross sectional view showing a mounting structure of an LED element in the eighteenth preferred embodiment according to the invention.

The LED element 101 is composed such that a glass member 130 with a high refractive index and a wiring pattern 122 is bonded through a transparent adhesive 142 onto the surface of the n-GaN layer 112 of the LED element 101 as shown in FIG. 23.

The p-contact electrode 115 of the LED element 101 is made of Rh.

The transparent adhesive 142 is an epoxy adhesive which does not block the transmission of light emitted from the LED element 101.

The n-external electrode 117 and the p-external electrode 118 are electrically connected through the transparent and conductive adhesive 142 to the wiring pattern 122. The adhesive 142 can be, as described earlier, epoxy resin containing a conductive filler.

In operation, when power is supplied connecting the wiring pattern 122 to a power supply (not shown), a forward voltage is applied through the n-external electrode 117 and the p-external electrode 118 of the LED element 101 to the light-emitting layer 113. Thereby, radiative recombination of hole and electron occurs in the light-emitting layer 113 and blue light is emitted. Blue light irradiated to the n-GaN layer 112 is externally radiated passing through the n-GaN layer 112, the transparent adhesive 142 and then the glass member 130. In contrast, blue light irradiated to the p-contact electrode 115 is reflected on the p-contact electrode 115 made of Rh and then externally radiated passing through the n-GaN layer 112, the transparent adhesive 142 and then the glass member 130.

On the other hand, a light component reflected on the interface of the glass member 130 and then laterally propagated through the GaN-based semiconductor layer 200 can be externally radiated after it is entered into an adhesive 120B from the side of the LED element 101.

### Effects of the Eighteenth Embodiment

In the eighteenth embodiment, since the LED element 101 is bonded through the transparent adhesive 142 onto the glass member 130, a light source suitable for a transmitting illumination such as a backlight can be offered.

Although in the eighteenth embodiment the p-contact electrode 115 is made of Rh with a light reflecting property, it may be made of a transparent material such as ITO so as to also extract light from the bottom of the GaN-based semiconductor layer 200.

### Nineteenth Embodiment

(Composition of LED Element 101)

FIG. 25A is a cross sectional view showing a large-size LED element (1 mm square) in the nineteenth preferred embodiment according to the invention. FIG. 25B is a top view showing the LED element in FIG. 25A, which is viewed from the side of an insulation layer formation surface thereof.

The LED element 101 is, as shown in FIG. 25B, composed of: a hole 101A which is formed at the center of the element and in the depth direction from the p-GaN layer 114 to the n-GaN layer 112; an n-external electrode 117 formed covering the n-GaN layer 112 exposed by etching inside the hole 10A; and a p-external electrode 118 formed covering the periphery of the GaN-based semiconductor layer 200 and electrically connected to the p-contact electrode 115. The p-contact electrode 115 of the LED element 101 is made of Rh.

The LED element 101 can be flip-chip bonded onto a board (not shown) which is provided with a wiring pattern corresponding to a pattern of solder plating that corresponds to the n-external electrode 117 and the p-external electrode 118.

### Effects of the Nineteenth Embodiment

In the nineteenth embodiment, since the n-external electrode 117 is disposed at the center of the element and the p-external electrode 118 are formed on the periphery of the element, even the large size LED element 101 can render the entire surface of the light-emitting layer 113 uniformly emit light.

By flip-chip mounting the LED element 101, a good emission property can be obtained while securing a good heat radiation property to the mounting board etc.

In the nineteenth embodiment, when the LED element 101 is mounted in face-up disposition, the p-contact electrode 115 may be made of a transparent material such as ITO. Thereby, a good wire bonding property can be obtained while preventing a reduction in light extraction efficiency as much as possible in the case of the face-up mounting.

Although the abovementioned embodiments relate to the light emitting element (=LED element), the invention is not limited to the light emitting element and may be applied to another optical element (or device) such as a solar cell and a light-receiving element and a method of making the same.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A light emitting element, comprising:
a semiconductor layer comprising a light-emitting layer;
a first electrode that is defined corresponding to the light-emitting layer to supply power to the light-emitting layer;
a second electrode that is defined as a counter electrode of the first electrode;
an insulation layer that is formed on a mounting face side of the semiconductor layer; and
a first terminal and a second terminal that are formed on a surface of the insulation layer corresponding to the first electrode and the second electrode, respectively,
wherein the first electrode and the second electrode are formed on the mounting face side of the semiconductor layer,
the insulation layer comprises a first opening and a second opening that are formed corresponding to the first electrode and the second electrode, respectively, and
the first electrode and the second electrode are electrically connected through the first hole and the second hole, respectively, to the first terminal and the second terminal.

2. The light emitting element according to claim 1, wherein:
the second electrode comprises a narrow line, and
the narrow line has a width of 50 μm or less.

3. The light emitting element according to claim 1, wherein:
the first terminal and the second terminal have a width of 100 μm or more.

4. The light emitting element according to claim 1, wherein:
the second terminal has an area greater than the second electrode.

5. A light emitting element, comprising:
a semiconductor layer comprising a light-emitting layer;
a first electrode that is defined corresponding to the light-emitting layer to supply power to the light-emitting layer;
a second electrode that is defined as a counter electrode of the first electrode;
wherein the first electrode and the second electrode are formed on the mounting face side of the semiconductor layer, and
the light-emitting layer and the first electrode are surrounded by the second electrode.

6. The light emitting element according to claim 5, wherein:
the light-emitting layer surrounded by the second electrode comprises an uneven end face.

7. The light emitting element according to claim 5, wherein:
a plurality of the light-emitting layers and a plurality of the first electrodes corresponding the plurality of the light-emitting layers are surrounded by the second electrode.

8. The light emitting element according to claim 1, wherein:
the first electrode has a surface area ratio of 60% or more relative to the light emitting element.

9. The light emitting element according to claim 5, wherein:
the first electrode has a surface area ratio of 60% or more relative to the light emitting element.

10. The light emitting element according to claim 1, wherein:
the light-emitting layer is formed symmetrical with respect to axes that are orthogonal to each other with respect to a center axis of the light emitting element.

11. The light emitting element according to claim 5, wherein:
the light-emitting layer is formed symmetrical with respect to axes that are orthogonal to each other with respect to a center axis of the light emitting element.

12. The light emitting element according to claim 1, wherein:
the second electrode comprises a part formed in a region of the first electrode.

13. The light emitting element according to claim 5, wherein:
the second electrode comprises a part formed in a region of the first electrode.

14. The light emitting element according to claim 1, wherein:
the semiconductor layer comprises a GaN-based semiconductor,
the first electrode is a p-type electrode, and
the second electrode is an n-type electrode.

15. The light emitting element according to claim 5, wherein;
the semiconductor layer comprises a GaN-based semiconductor,
the first electrode is a p-type electrode, and
the second electrode is an n-type electrode.

16. A light emitting element, comprising:
a semiconductor layer comprising a light-emitting layer; and
an n-type electrode and a p-type electrode to supply power to the light-emitting layer,
wherein the n-type electrode and the p-type electrode are provided at a periphery of the semiconductor layer that has a width smaller than an entire width of the light emitting element.

17. The light emitting element according to claim 16, wherein:
the periphery is formed by partially removing the semiconductor layer in a same direction as a stack direction of the semiconductor layer.

18. The light emitting element according to claim 16, wherein:
the n-type electrode and the p-type electrode are provided at the periphery of the semiconductor layer through an insulation layer comprising a transparent material with a refractive index different from the semiconductor layer, and
the n-type electrode and the p-type electrode are electrically connected to an n-type layer and a p-type layer, respectively.

19. The light emitting element according to claim 16, wherein:
the n-type electrode and the p-type electrode are, in mounting the light emitting element, electrically connected at a part exposed to the periphery of the semiconductor layer while allowing a sapphire substrate as an underlying substrate of the semiconductor layer to be in close contact with a mounting face.

20. The light emitting element according to claim 16, wherein:
the n-type electrode and the p-type electrode are electrically connected to an external circuit at a part exposed to the periphery of the semiconductor layer while allowing the semiconductor layer to be in close contact with a mounting face.

21. The light emitting element according to claim 16, wherein:
the n-type electrode and the p-type electrode comprise an n-type electrode provided inside of a hole formed in the semiconductor layer, and a p-type electrode provided outside of the semiconductor layer.

22. The light emitting element according to claim 16, wherein:
the semiconductor layer comprises a group III nitride-based compound semiconductor.

23. A method of making a light emitting element, comprising:
a semiconductor layer formation step of forming a semiconductor layer comprising a light-emitting layer by stacking a semiconductor material on a wafer underlying substrate;
a semiconductor layer removal step of partially removing the semiconductor layer in a predetermined width and a predetermined depth from a surface of the semiconductor layer to formed an exposed portion;
an electrode formation step of forming electrodes to supply power to an n-type layer and a p-type layer of the semiconductor layer at the exposed portion; and
an element formation step of cutting the underlying substrate with the semiconductor layer into a light emitting element to allow the electrodes to be exposed to a periphery of the light emitting element.

24. The method according to claim 23, wherein:
the electrode formation step comprises:
an insulation layer formation step of forming an insulation layer to cover a surface of the semiconductor layer and the exposed portion;
an insulation layer removal step of removing the insulation layer while securing an insulation between the n-type layer and the p-type layer to form electrode formation regions corresponding to the n-type layer and the p-type layer; and
an-external electrode formation step of forming external electrodes to be connected to the n-type layer and the p-type layer in the corresponding electrode formation regions.

25. The method according to claim 24 wherein:
the external electrode formation step comprises:
a first external electrode formation step of forming a first external electrode to be connected to the n-type layer; and
a second external electrode formation step of forming a second external electrode to be connected to the p-type layer.

26. The method according to claim 24 wherein:
the external electrode formation step comprises:
a first external electrode formation step of forming a first external electrode to be connected to the n-type layer; and
a second external electrode formation step of forming a second external electrode to be connected to the p-type layer,
wherein the first external electrode formation step and the second external electrode formation step are conducted simultaneously.

27. The method according to claim 23 wherein:
the semiconductor layer formation step comprising a step of forming a contact electrode made of a light reflecting material on the p-type layer.

28. The method according to claim 23 wherein:
the semiconductor layer formation step comprising a step of forming a contact electrode made of a light transmitting material on the p-type layer.
